(19) United States
(12) Patent Application Publication
(10) Pub. No.: US 2025/0384831 A1
(43) Pub. Date: Dec. 18, 2025

(54) DISPLAY DEVICE, AND ELECTRONIC DEVICE INCLUDING THE SAME

(71) Applicant: Samsung Display Co., Ltd., Yongin-si (KR)

(72) Inventor: Jong Hyun CHOI, Yongin-si (KR)

(21) Appl. No.: 19/076,374

(22) Filed: Mar. 11, 2025

(30) Foreign Application Priority Data
Jun. 17, 2024 (KR) 10-2024-0078159

(51) Int. Cl. G09G 3/3233; H10K 59/121; H10K 59/131

(52) U.S. Cl. CPC G09G 3/3233; G09G 2300/0426; G09G 2300/0819; G09G 2300/0842; G09G 2300/0861; G09G 2310/08; H10K 59/1213; H10K 59/131

(57) ABSTRACT

A display device includes a first light-emitting element, a second light-emitting element, a first transistor configured to connect a first data line and a first node based on a first signal, a first capacitor connected to the first node, a second transistor connected between the first light-emitting element and a common node, and configured to provide a first current based on the first voltage to the first light-emitting element, a third transistor configured to connect the first data line and a second node based on a second signal, a second capacitor connected to the second node, a fourth transistor connected between the second light-emitting element and the common node, and configured to provide a second current based on the second voltage to the second light-emitting element, and a fifth transistor configured to connect a power voltage line and the common node.

This application claims priority to Korean Patent Application No. 10-2024-0078159, filed on Jun. 17, 2024, and all the benefits accruing therefrom under 35 U.S.C. § 119, the content of which in its entirety is herein incorporated by reference.

### BACKGROUND

### 1. Field of the Disclosure

The present disclosure relates to a display device.

### 2. Description of the Related Art

An electronic device such as a smartphone, a digital camera, a laptop computer, a navigation system, or a smart television that provides an image to a user may include a display device displaying the image. The display device may generate the image and provide the image to the user through a display screen.

In relation to the display device, research has been conducted to provide a function of high-speed driving or variable frequency driving that provides the user with the image that is switched at a high-frame frequency, thus increasing the number of elements and wires disposed in pixels of the display device.

Therefore, there is a need for a technology of reducing signal wiring and power wiring in the display device in order to solve the above-mentioned problem and overcome a resolution constraint.

### SUMMARY

The present disclosure attempts to provide a display device in which an individual pixel shares a portion of a circuit with its adjacent pixel without affecting the adjacent pixel when performing a compensation operation on the individual pixel.

According to an embodiment, provided is a display device including: a first light-emitting element and a second light-emitting element; a first transistor configured to connect a first data line and a first node to each other based on a first signal; a first capacitor including one electrode connected to the first node, and configured to store a first voltage based on a data signal transmitted through the first data line and corresponding to a first current to be provided to the first light-emitting element; a second transistor connected between the first light-emitting element and a common node, and configured to provide the first current based on the first voltage to the first light-emitting element; a third transistor configured to connect the first data line and a second node to each other based on a second signal different from the first signal; a second capacitor including one electrode connected to the second node, and configured to store a second voltage based on a data signal transmitted through the first data line and corresponding to a second current to be provided to the second light-emitting element; a fourth transistor connected between the second light-emitting element and the common node, and configured to provide the second current based on the second voltage to the second light-emitting element; and a fifth transistor configured to connect a power voltage line and the common node to each other based on a third signal.

The device may further include a sixth transistor configured to provide a first reference voltage to the common node based on a fourth signal.

The device may further include: a seventh transistor configured to provide a second reference voltage to the first node based on a fifth signal; an eighth transistor configured to provide an initialization voltage to an anode of the first light-emitting element based on a sixth signal; a ninth transistor configured to provide the second reference voltage to the second node based on a seventh signal; and a tenth transistor configured to provide the initialization voltage to an anode of the second light-emitting element based on an eighth signal, wherein the second transistor provides the first current to the first light-emitting element through a third node, the fourth transistor is configured to provide the second current to the second light-emitting element through a fourth node, the other electrode of the first capacitor is connected to the third node, and the other electrode of the second capacitor is connected to the fourth node.

The sixth transistor, the eighth transistor, and the tenth transistor may be configured to be turned on simultaneously.

The device may further include: a third capacitor including one electrode connected to the first node and the other electrode connected to the power voltage line; a fourth capacitor including one electrode connected to the second node and the other electrode connected to the power voltage line; a seventh transistor configured to provide the first reference voltage to the first node based on a fifth signal; an eighth transistor configured to connect a third node and a control terminal of the second transistor to each other based on the fifth signal; a ninth transistor configured to provide the first reference voltage to the second node based on a sixth signal; and a tenth transistor configured to connect a fourth node and a control terminal of the fourth transistor to each other based on the sixth signal, wherein the first capacitor is connected between the first node and the control terminal of the second transistor, and the second capacitor is connected between the second node and the control terminal of the fourth transistor.

The device may further include an eleventh transistor configured to provide a light-emission initialization voltage to an anode of the first light-emitting element based on the fourth signal.

The first transistor, the seventh transistor, and the eighth transistor may be P-type metal oxide semiconductor (“PMOS”) transistors.

The first transistor, the seventh transistor, and the eighth transistor may be N-type metal oxide semiconductor (NMOS) transistors, and the second transistor, the fifth transistor, and the sixth transistor may be P-type metal oxide semiconductor (PMOS) transistors.

The device may further include: a third light-emitting element and a fourth light-emitting element; a seventh transistor configured to connect a second data line, which is different from the first data line, and a third node to each other based on the first signal; a third capacitor including one electrode connected to the third node, and configured to store a third voltage based on a data signal transmitted through the second data line and corresponding to a third current to be provided to the third light-emitting element; an eighth transistor connected between the common node and the third light-emitting element, and configured to provide the third current based on the third voltage to the third light-emitting element; a ninth transistor configured to connect the second data line and a fourth node to each other based on the second signal; a fourth capacitor including one electrode connected to the fourth node, and configured to store a fourth voltage based on a data signal transmitted through the second data line and corresponding to a fourth current to be provided to the fourth light-emitting element; and a tenth transistor connected between the common node and the fourth light-emitting element, and configured to provide the fourth current based on the fourth voltage to the fourth light-emitting element.

The first transistor, the third transistor, and the fifth transistor may be configured to be turned on sequentially, and the first and second light-emitting elements may be configured to emit light.

According to an embodiment, provided is a display device including: a first light-emitting element and a second light-emitting element; a first transistor configured to connect a first data line and a first node to each other based on a first signal; a first capacitor connected between the first node and a second node, and configured to store a first voltage based on a data signal transmitted through the first data line and corresponding to a first current to be provided to the first light-emitting element; a second transistor connected between the second node and a common node, and configured to provide the first current based on the first voltage to the first light-emitting element; a third transistor configured to connect the first data line and a third node to each other based on a second signal different from the first signal; a second capacitor connected between the third node and a fourth node, and configured to store a second voltage based on a data signal transmitted through the first data line corresponding to a second current to be provided to the second light-emitting element; a fourth transistor connected between the fourth node and the common node, and configured to provide the second current based on the second voltage to the second light-emitting element; and a fifth transistor configured to connect a power voltage line and the common node to each other based on a third signal.

The device may further include: a third light-emitting element and a fourth light-emitting element; a sixth transistor configured to connect a second data line, which is different from the first data line, and a fifth node to each other based on the first signal; a third capacitor connected between the fifth node and a sixth node, and configured to store a third voltage based on a data signal transmitted through the second data line and corresponding to a third current to be provided to the third light-emitting element; a seventh transistor connected between the common node and the third light-emitting element, and configured to provide the third current based on the third voltage to the third light-emitting element; an eighth transistor configured to connect the second data line and a seventh node to each other based on the second signal; a fourth capacitor connected between the seventh node and an eighth node, and configured to store a fourth voltage based on a data signal transmitted through the second data line and corresponding to a fourth current to be provided to the fourth light-emitting element; and a ninth transistor connected between the common node and the fourth light-emitting element, and configured to provide the fourth current based on the fourth voltage to the fourth light-emitting element.

The first transistor and the second transistor may be disposed in a first area, the third transistor and the fourth transistor may be disposed in a second area adjacent to the first area in a first direction in which the first data line extends, the sixth transistor and the seventh transistor may be disposed in a third area adjacent to the first area in a second direction intersecting the first direction, the eighth transistor and the ninth transistor may be disposed in a fourth area adjacent to the second area in the second direction and adjacent to the third area in the first direction, and the fifth transistor may be disposed in a fifth area disposed between the first to fourth areas.

The device may further include: a fifth capacitor connected between the second node and the power voltage line; a sixth capacitor connected between the fourth node and the power voltage line; a seventh capacitor connected between the sixth node and the power voltage line; and an eighth capacitor connected between the eighth node and the power voltage line, wherein one electrode of each of the fifth to eighth capacitors is disposed in the fifth area.

The device may further include: a tenth transistor configured to provide a first reference voltage to the common node based on a fourth signal, and the tenth transistor may be disposed in the fifth area.

While compensation operations are performed on the second transistor and the fourth transistor, the second transistor and the fourth transistor may be configured to operate as source followers

The first to fifth transistors may be N-type metal oxide semiconductor (“NMOS”) transistors.

According to an embodiment, provided is an electronic device including: a plurality of pixels including a first pixel and a second pixel, where the first pixel and the second pixel share a common circuit disposed therebetween and are connected to a first data line; a scan driver configured to provide a scan signal to each of the plurality of pixels; and a light emission driver configured to provide a light-emitting signal to each of the plurality of pixels, wherein each of the first pixel and the second pixel includes a first light-emitting element, a first transistor configured to connect the first data line and a first node to each other based on a first signal, a first capacitor including one electrode connected to the first node, and configured to store a first voltage based on a data signal transmitted through the first data line and corresponding to a first current to be provided to the first light-emitting element, and a second transistor connected between a common node and the first light-emitting element, and configured to provide the first current based on the first voltage to the first light-emitting element, and the common circuit includes a third transistor configured to connect the common node and a power voltage line to each other based on the light-emitting signal.

The plurality of pixels may further include a third pixel and a fourth pixel connected to a second data line, which is different from the first data line, and sharing the common circuit, and each of the third pixel and the fourth pixel may include a second light-emitting element, a first transistor configured to connect the second data line and a second node to each other based on a second signal, a second capacitor including one electrode connected to the second node, and configured to store a second voltage based on a data signal transmitted through the second data line and corresponding to a second current to be provided to the second light-emitting element and transmitted through the second data line, and a second transistor connected between the common node and the second light-emitting element, and configured to provide the second current based on the second voltage to the second light-emitting element.

The first pixel and the second pixel may be adjacent to each other in a first direction in which the first data line extends, the first pixel and the third pixel may be adjacent to each other in a second direction intersecting the first direction, the fourth pixel may be adjacent to the third pixel in the first direction and adjacent to the second pixel in the second direction, and the common circuit may be disposed between the first to fourth pixels.

According to the embodiments, the display device may overcome the resolution constraint problem of the panel by reducing the number of elements and signal wiring in the panel while performing the compensation operation on the individual pixel without being affected by the adjacent pixel.

According to an embodiment, provided is a display device including: a memory; a processor executing an application stored in the memory; and a display device comprising a display module outputting video information provided by the application, wherein the display device comprises: a first light-emitting element and a second light-emitting element; a first transistor configured to connect a first data line and a first node to each other based on a first signal; a first capacitor including a first electrode connected to the first node, and configured to store a first voltage based on a data signal transmitted through the first data line and corresponding to a first current to be provided to the first light-emitting element; a second transistor connected between the first light-emitting element and a common node, and configured to provide the first current based on the first voltage to the first light-emitting element; a third transistor configured to connect the first data line and a second node to each other based on a second signal different from the first signal; a second capacitor including a first electrode connected to the second node, and configured to store a second voltage based on a data signal transmitted through the first data line and corresponding to a second current to be provided to the second light-emitting element; a fourth transistor connected between the second light-emitting element and the common node, and configured to provide the second current based on the second voltage to the second light-emitting element; and a fifth transistor configured to connect a power voltage line and the common node to each other based on a third signal.

### BRIEF DESCRIPTION OF THE DRAWINGS

FIG. 1 is a schematic plan view of a display device according to an embodiment.

FIG. 2 is a cross-sectional view exemplarily showing a cross-section of the display device of FIG. 1.

FIG. 3 is a cross-sectional view exemplarily showing a cross-section of a display panel of FIG. 2.

FIG. 4 is a plan view exemplarily showing a plane of the display panel of FIG. 3.

FIG. 5 is an enlarged view showing area AA of FIG. 4.

FIG. 6 is an equivalent circuit diagram of one pixel included in the display device according to an embodiment.

FIG. 7 is a circuit diagram of a pixel group included in the display device according to an embodiment.

FIG. 8 is a timing diagram for explaining driving of a pixel in the display device according to an embodiment.

FIG. 9 is a timing diagram for explaining driving of a pixel in the display device according to an embodiment.

FIG. 10 is an equivalent circuit diagram of one pixel included in the display device according to an embodiment.

FIG. 11 is a circuit diagram of a pixel group included in the display device according to an embodiment.

FIG. 12 is a timing diagram for explaining driving of a pixel in the display device according to an embodiment.

FIG. 13 is an equivalent circuit diagram of one pixel included in the display device according to an embodiment.

FIG. 14 is a circuit diagram of a pixel group included in the display device according to an embodiment.

FIG. 15 is a timing diagram for explaining driving of a pixel in the display device according to an embodiment.

FIG. 16 is an equivalent circuit diagram of one pixel included in the display device according to an embodiment.

FIG. 17 is a circuit diagram of a pixel group included in the display device according to an embodiment.

FIG. 18 is a timing diagram for explaining driving of a pixel in the display device according to an embodiment.

FIG. 19 is a block diagram of an electronic device according to some embodiments.

FIG. 20 shows schematic diagrams of electronic devices according to various embodiments.

### DETAILED DESCRIPTION

Various advantages and features of the present disclosure and methods accomplishing the same are become apparent from embodiments described in detail below with reference to the accompanying drawings. However, the present disclosure is not limited to the embodiments disclosed below, and may be implemented in various different forms. These embodiments are provided only in order to make the present disclosure complete and allow those skilled in the art to completely appreciate the scope of the present disclosure, and the present disclosure is defined only by the scope of the claims. Throughout the specification, like reference numerals denote like elements.

When an element or layer is mentioned to be “on” another element or layer, the corresponding element or layer may be directly on another element or layer, or the corresponding element or layer may be “above” another element or layer while having a third element or layer interposed threbetween. On the other hand, when an element is “directly on” another element, there is no third element interposed threbetween.

“And/or” includes each and every combination of one or more of the items mentioned.

A term expressing a spatial relationship such as “below”, “beneath”, “lower”, “above”, or “upper” may be used to easily describe a relationship between one element or components and another element or other components, as shown in the drawings. The term expressing a spatial relationship should be understood as a term that includes different directions of an element when the element is used or operated in addition to its directions shown in the drawings. Throughout the specification, like reference numerals denote like elements.

Although terms such as “first”, “second”, 1-a-th, 2-a-th, 1-b-th, 2-b-th, etc. are used to describe various elements, components, and/or sections, it is apparent that these elements, components, and/or sections are not limited to these terms. These terms are only used to distinguish one element, component, or section and another element, component, or section from each other. Therefore, it is apparent that a first element, a first component, or a first section, described below, may also be a second element, a second component, or a second section, within the spirit of the present disclosure.

The embodiments described in this specification are described with reference to the plan and cross-sectional views of the present disclosure, which are its ideal schematic views. Therefore, exemplified forms may be changed by manufacturing technologies and/or tolerance. Therefore, the embodiments of the present disclosure are not limited to the specific forms shown in the drawings, and also include changes in their forms produced based on a manufacturing process. Therefore, an area shown in the drawing has schematic attributes, and a shape of the area shown in the drawing is provided for exemplifying a specific shape rather than limiting the scope of the present disclosure.

Hereinafter, the embodiments of the present disclosure are described in detail with reference to the accompanying drawings.

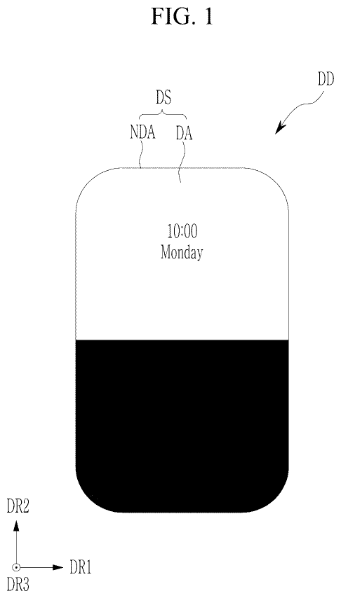

FIG. 1 is a schematic plan view of a display device according to an embodiment.

Referring to FIG. 1, a display device DD according to an embodiment of the present disclosure may have a rectangular shape having a short side extending in a first direction DR1 and a long side extending in a second direction DR2 intersecting the first direction DR1. However, the display device DD is not limited thereto, and may have any of various shapes such as circular and polygonal shapes. According to an embodiment, the display device DD may be a flexible display device, and is not limited thereto.

An upper surface of the display device DD may be defined as a display surface DS, and the display surface DS may have a plane defined by the first direction DR1 and the second direction DR2. A user may be provided with an image or images generated by the display device DD through the display surface DS.

The display surface DS may include a display area DA and a non-display area NDA surrounding the display area DA.

The display area DA may display the image, and the non-display area NDA may not display any image. The non-display area NDA may surround the display area DA and be printed in a predetermined color to thus define a border of the display device DD.

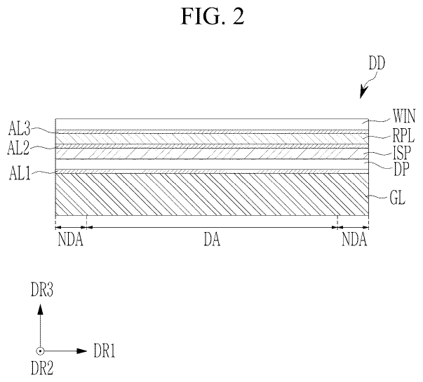

FIG. 2 is a cross-sectional view exemplarily showing a cross-section of the display device of FIG. 1. As an exemplary view, FIG. 2 shows a cross-section of the display device DD viewed from the second direction DR2.

Referring to FIGS. 1 and 2, the display device DD may include a display panel DP, an input sensing part ISP, an reflection prevention layer RPL, a window WIN, a support layer GL, and first to third adhesive layers AL1 to AL3.

The display panel DP may be an emissive display panel, and is not limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include a quantum dot, a quantum rod, or the like. According to an embodiment, the display panel DP may be a flexible display panel, and is not limited thereto.

The input sensing part ISP may be disposed on the display panel DP. The input sensing part ISP may include a plurality of sensor parts (not shown) sensing external input in a capacitive manner. The input sensing part ISP may be manufactured directly on the display panel DP when manufacturing the display device DD. However, the input sensing part ISP is not limited thereto, and may be manufactured as a panel separate from the display panel DP to be attached to the display panel DP by an adhesive layer.

The reflection prevention layer RPL may be disposed on the input sensing part ISP. The reflection prevention layer RPL may be an external light reflection prevention film. The reflection prevention layer RPL may reduce reflectivity of external light incident from above the display device DD toward the display panel DP.

External light directed toward the display panel DP may be reflected by the display panel DP and provided to the user outside again. In this case, external light may be visible to the user like a mirror. To prevent this phenomenon, for example, the reflection prevention layer RPL may include a plurality of color filters that display the same colors as pixels of the display panel DP.

The color filters may filter external light to the same colors as those of the pixels. In this case, external light may not be visible to the user. However, the reflection prevention layer RPL is not limited thereto, and may include a polarizing film including a phase retarder and/or a polarizer to reduce the reflectivity of external light.

The window WIN may be disposed on the reflection prevention layer RPL. The window WIN may protect the display panel DP, the input sensing part ISP, and the reflection prevention layer RPL from external scratches and impacts.

The support layer GL may be disposed under the display panel DP. The support layer GL may protect a back surface of the display panel DP. The support layer GL may include glass. According to an embodiment, the support layer GL may be folded together with the display panel DP.

The first adhesive layer AL1 may be disposed between the display panel DP and the support layer GL, and the display panel DP and the support layer GL may be bonded to each other by the first adhesive layer AL1. The second adhesive layer AL2 may be disposed between the reflection prevention layer RPL and the input sensing part ISP, and the reflection prevention layer RPL and the input sensing part ISP may be bonded to each other by the second adhesive layer AL2. The third adhesive layer AL3 may be disposed between the window WIN and the reflection prevention layer RPL, and the window WIN and the reflection prevention layer RPL may be bonded to each other by the third adhesive layer AL3.

Although not shown in the drawings, the display device DD may further include a panel protection film disposed under the support layer GL.

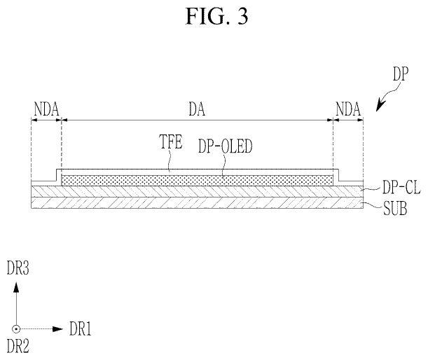

FIG. 3 is a cross-sectional view exemplarily showing a cross-section of the display device of FIG. 2. As an exemplary view, FIG. 3 shows a cross-section of the display panel DP viewed from the second direction DR2.

Referring to FIGS. 2 and 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA and the non-display area NDA surrounding the display area DA. According to an embodiment, the substrate SUB may include a flexible plastic material such as polyimide PI, and is not limited thereto. The display element layer DP-OLED may be disposed on the display area DA.

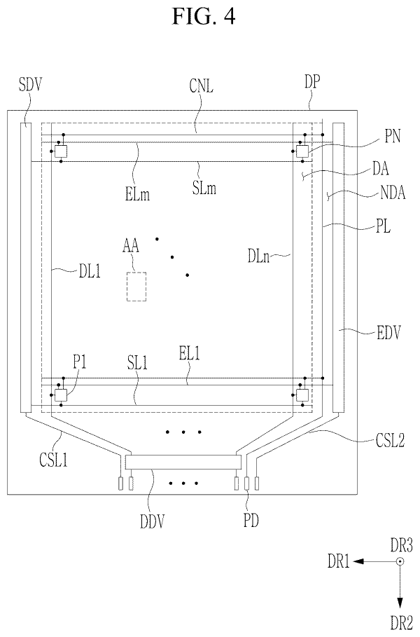

A plurality of pixels P1 to PN described below with reference to FIG. 4 may be disposed in the display area DA. Each pixel may include a light-emitting element OLED disposed in the display element layer DP-OLED and connected to a transistor disposed in the circuit element layer DP-CL. A connection relationship between the transistor and the light-emitting element OLED is described in detail below.

The thin film encapsulation layer TFE may be disposed on the display element layer DP-OLED and the circuit element layer DP-CL to cover the display element layer DP-OLED and the circuit element layer DP-CL. The thin film encapsulation layer TFE may include inorganic layers and an organic layer between the inorganic layers. The inorganic layer may protect the pixel from moisture/oxygen. The organic layer may protect the pixel from a foreign material such as a dust particle.

FIG. 3 shows that the display element layer DP-OLED is disposed on the circuit element layer DP-CL, is not limited thereto, and the circuit element layer DP-CL may be disposed on the display element layer DP-OLED according to an embodiment.

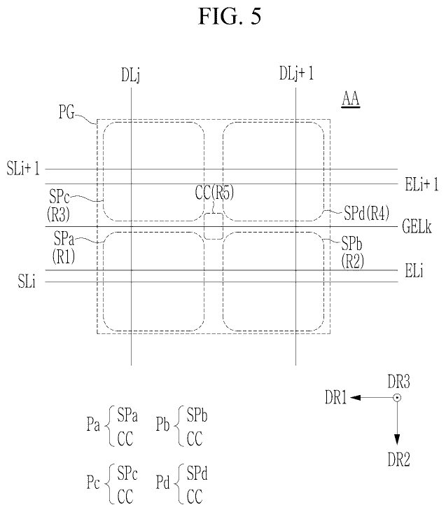

FIG. 4 is a plan view exemplarily showing a plane of the display panel of FIG. 3. FIG. 5 is an enlarged view showing area AA of FIG. 4.

Referring to FIGS. 3 to 5, the display panel DP may include a scan driver SDV, a data driver DDV, a light emission driver EDV, and a plurality of pads PD.

The display panel DP may have a rectangular shape having a short side extending in the first direction DR1 and a long side extending in the second direction DR2, and is not limited to this shape. The display panel DP may include the display area DA and the non-display area NDA surrounding the display area DA.

The display panel DP may include the plurality of pixels P1 to PN, a plurality of scan lines SL1 to SLm, a plurality of data lines DL1 to DLn, a plurality of light-emitting lines EL1 to ELm, first and second control lines CSL1 and CSL2, a power line PL, and a connection line CNL. Hereinafter, m or n is a natural number of 2 or more.

The plurality of pixels P1 to PN may be disposed in the display area DA. The scan driver SDV and the light emission driver EDV may be disposed in the non-display area NDA adjacent to the respective long sides of the display panel DP. The data driver DDV may be disposed in the non-display area NDA adjacent to one of the short sides of the display panel DP. In plan view, the data driver DDV may be adjacent to a lower end of the display panel DP.

The plurality of scan lines SL1 to SLm may be connected to the plurality of pixels P1 to PN and the scan driver SDV by extending in the first direction DR1. The plurality of data lines DL1 to DLn may be connected to the plurality of pixels P1 to PN and the data driver DDV by extending in the second direction DR2. The plurality of light-emitting lines EL1 to ELm may be connected to the pixels P1 to PN and the light emission driver EDV by extending in the first direction DR1.

The power line PL may be disposed in the non-display area NDA by extending in the second direction DR2. According to an embodiment, the power line PL may be disposed between the display area DA and the light emission driver EDV.

The plurality of connection lines CNL may be connected to the power line PL and the plurality of pixels P1 to PN by extending in the first direction DR1 and being arranged in the second direction DR2. A first power voltage may be applied to the plurality of pixels P1 to PN through the power line PL and the connection line CNL, which are connected to each other. The connection line CNL may actually be a portion of the power line PL that receives the first power voltage.

Although not shown in the drawings, a separate low-potential power line may be disposed to provide the display panel DP with a second power voltage having a level lower than the first power voltage. According to an embodiment, the low-potential power line may be disposed in the non-display area NDA, and extend along the long side of the display panel DP or along the other short side of the display panel DP, where the data driver DDV is not disposed. The low-potential power line may be disposed outside the scan driver SDV and the light emission driver EDV.

The first control line CSL1 may be connected to the scan driver SDV and extend toward the lower end of the display panel DP. The second control line CSL2 may be connected to the light emission driver EDV and extend toward the lower end of the display panel DP.

The plurality of pads PD may be disposed in the non-display area NDA adjacent to the lower end of the display panel DP. According to an embodiment, the plurality of pads PD may be closer to the lower end of the display panel DP than the data driver DDV. The data driver DDV, the power line PL, the first and second control lines CSL1 and CSL2 may be connected to the plurality of pads PD. The data lines DL1 to DLn may be connected to the data driver DDV, and the data driver DDV may be connected to the pads corresponding to the data lines DL1 to DLn.

Although not shown in the drawings, the display device DD (of FIG. 1) may further include a timing controller controlling operations of the scan driver SDV, the data driver DDV, and the light emission driver EDV, and a voltage generator generating the first and second power voltages. The timing controller and the voltage generator may be connected to the plurality of pads PD corresponding thereto through a printed circuit board.

The scan driver SDV may receive a first control signal from the timing controller through the first control line CSL1. Similarly, the light emission driver EDV may receive a second control signal from the timing controller through the second control line CSL2. The timing controller may control the scan driver SDV and the light emission driver EDV through the first control signal and the second control signal. The first and second control signals may include a vertical start signal and a gate clock signal.

The scan driver SDV may generate a plurality of scan signals, and the plurality of scan signals may be applied to the plurality of pixels P1 to PN through the plurality of scan lines SL1 to SLm. The data driver DDV may generate a data voltage, and the data voltage may be applied as a data signal to the plurality of pixels P1 to PN through the plurality of data lines DL1 to DLn. The light emission driver EDV may generate a plurality of light-emitting signals, and the plurality of light-emitting signals may be applied to the plurality of pixels P1 to PN through the light-emitting lines EL1 to Elm.

Each of the plurality of pixels P1 to PN may receive the data voltage as the data signal based on the scan signal. The plurality of pixels P1 to PN may display the image by emitting light of a brightness corresponding to the data voltage based on the light-emitting signal.

Referring to FIG. 5 as an example, the plurality of pixels P1 to PN may include an a-th pixel Pa and a c-th pixel Pc adjacent to each other in the second direction DR2, and a b-th pixel Pb and a d-th pixel Pd adjacent to each other in the second direction DR2. The a-th pixel Pa and the b-th pixel Pb may be adjacent to each other in the first direction DR1, and the c-th pixel Pc and the d-th pixel Pd may be adjacent to each other in the first direction DR1. In the present disclosure, homogeneous components ‘adjacent to each other’ may indicate that another homogeneous component is not disposed between the adjacent components.

The a-th pixel Pa and the b-th pixel Pb may be connected to the i-th scan line SLi among the plurality of scan lines SL1 to SLm, and the c-th pixel Pc and the d-th pixel Pd may be connected to the i+1-th scan line SLi+1 among the plurality of scan lines SL1 to SLm. The i-th scan line SLi and the i+1-th scan line SLi+1 may be adjacent to each other in the second direction DR2. The a-th pixel Pa and the b-th pixel Pb may be connected to the i-th light-emitting line ELi among the plurality of light-emitting lines EL1 to ELm, and the c-th pixel Pc and the d-th pixel Pd may be connected to the i+1-th light-emitting line ELi+1 among the plurality of light-emitting lines EL1 to ELm. The i-th light-emitting line ELi and the i+1-th light-emitting line ELi+1 may be adjacent to each other in the second direction DR2. “i” may be any integer greater than or equal to 1 and less than “m”.

The a-th pixel Pa and the c-th pixel Pc may be connected to the j-th data line DLj among the plurality of data lines DL1 to DLn, and the b-th pixel Pb and the d-th pixel Pd may be connected to the j+1-th data line DLj+1 among the plurality of data lines DL1 to DLn. The j-th data line DLj and the j+1-th data line DLj+1 may be adjacent to each other in the first direction DR1. “j” may be any integer greater than or equal to 1 and less than “n”.

The a-th to d-th pixels Pa to Pd may receive the signals from the j-th and j+1-th data lines DLj and DLj+1, the i and i+1-th scan lines SLi and SLi+1, and the i-th and i+1-th light-emitting lines Eli and ELi+1 to thus emitting light, thereby displaying the image. To describe the a-th pixel Pa as an example, the a-th pixel Pa may receive the data voltage as the data signal from the j-th data line DLj based on the scan signal provided through the i-th scan line SLi, and display the image by emitting light having a brightness corresponding to the data voltage based on the light-emitting signal provided through the i-th light-emitting line ELi. The b-th to d-th pixels Pb to Pd may be driven in the same manner as the a-th pixel Pa through the connected data lines, scan lines, and light-emitting lines.

The a-th to d-th pixels Pa to Pd may share a common circuit CC adjacent to each pixel. One pixel group PG may include the a-th to d-th pixels Pa to Pd that share the common circuit CC. The a-th pixel Pa may be operated as one pixel displaying the image by performing its light-emitting operation through an a-th individual pixel circuit SPa and the common circuit CC. The b-th pixel Pb may be operated as one pixel displaying the image by performing its light-emitting operation through a b-th individual pixel circuit SPb and the common circuit CC. The c-th pixel Pc may be operated as one pixel displaying the image by performing its light-emitting operation through a c-th individual pixel circuit SPc and the common circuit CC. The d-th pixel Pd may be operated as one pixel displaying the image by performing its light-emitting operation through a d-th individual pixel circuit SPd and the common circuit CC.

The a-th individual pixel circuit SPa and the b-th individual pixel circuit SPb may be disposed in a first area R1 and a second area R2 adjacent to each other in the first direction DR1, respectively. The c-th individual pixel circuit SPc and the d-th individual pixel circuit SPd may respectively be disposed in a third area R3 and a fourth area R4 adjacent to each other in the first direction DR1. The first area R1 and the third area R3 may be adjacent to each other in the second direction DR2. The second area R2 and the fourth area R4 may be adjacent to each other in the second direction DR2.

The common circuit CC may be disposed in a space provided among the a-th individual pixel circuit SPa of the a-th pixel Pa, the b-th individual pixel circuit SPb of the b-th pixel Pb, the c-th individual pixel circuit SPc of the c-th pixel Pc, and the d-th individual pixel circuit SPd of the d-th pixel Pd. The common circuit CC may be disposed in a fifth area R5 provided among the first to fourth areas R1 to R4.

The common circuit CC may receive the light-emitting signal from a k-th group light-emitting line GELk that is adjacent to the i-th light-emitting line ELi and the i+1-th light-emitting line ELi+1 in the first direction DR1 and corresponds to the pixel group PG, and provide the first power voltage to the a-th to d-th individual pixel circuits SPa to SPd based on the received light-emitting signal.

The k-th group light-emitting line GELk may provide the light-emitting signal for simultaneously controlling the plurality of pixels connected to the i-th light-emitting line ELi and the i+1-th light-emitting line ELi+1 adjacent to each other. The a-th to d-th pixels Pa to Pd may receive a group light-emitting signal from the k-th group light-emitting line GELk to thus emit light, thereby displaying the image. According to an embodiment, “k” may be an absolute value of a value acquired by dividing “i” in half.

According to an embodiment, the common circuit CC may provide the first power voltage to one terminal of each driving transistor of the a-th to d-th individual pixel circuits SPa to SPd, and provide the first power voltage for the compensation operation or light-emitting operation of each of the a-th to d-th individual pixel circuits SPa to SPd. The specific connection relationship between the common circuit CC and the a-th to d-th individual pixel circuits SPa to SPd is described below.

According to an embodiment, the display panel DP may reduce signal wiring, such as a circuit element or a contact, to provide the first power voltage to the a-th to d-th individual pixel circuits SPa to SPd by using the common circuit CC.

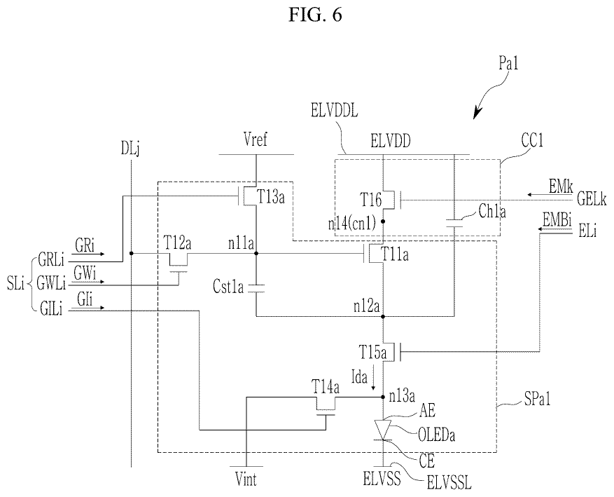

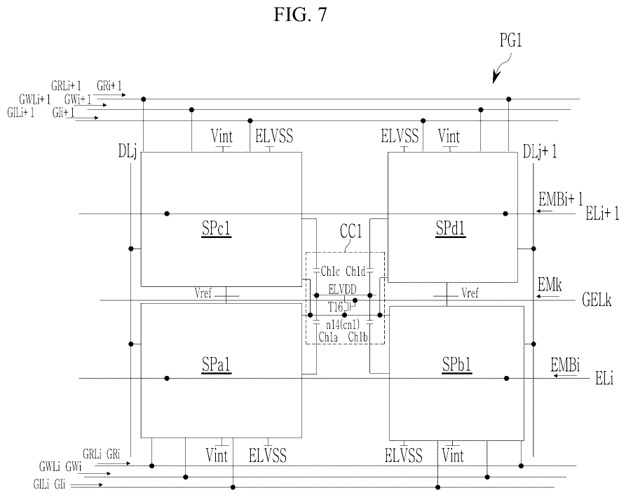

FIG. 6 is an equivalent circuit diagram of one pixel included in the display device according to an embodiment. FIG. 7 is a circuit diagram of a pixel group included in the display device according to an embodiment.

th to d-th individual pixel circuits SPa1 to SPd1, a common circuit CC1, an a-th pixel Pa1, and a pixel group PG1, shown in FIGS. 6 and 7, are respective examples of the a-th to d-th individual pixel circuits SPa to SPd, the common circuit CC, the a-th pixel Pa, and the pixel group PG, shown in FIG. 5. It is apparent that the descriptions of the a-th to d-th individual pixel circuits SPa to SPd, the common circuit CC, the a-th pixel Pa, and the pixel group PG, which are provided above with reference to FIG. 5, are applied to those of the a-th to d-th individual pixel circuits SPa1 to SPd1, the common circuit CC1, the a-th pixel Pa1, and the pixel group PG1.

Referring to FIGS. 5 to 7, the a-th pixel Pa1 may include the a-th individual pixel circuit SPa1 and share at least a portion of the common circuit CC1 with the b-th to d-th pixels. The a-th individual pixel circuit SPa1 may include a 1-a-th transistor T11a, a 2-a-th transistor T12a, a 3-a-th transistor T13a, a 4-a-th transistor T14a, a 5-a-th transistor T15a, a 1-a-th capacitor Cst1a, and an a-th light-emitting element OLEDa.

The common circuit CC1 may receive a k-th group light-emitting signal EMk from the k-th group light-emitting line GELk, and may provide a first power voltage ELVDD to the a-th individual pixel circuit SPa1 based on the k-th group light-emitting signal EMk. The common circuit CC1 may include a sixth transistor T16, and 2-a-th to 2-d-th capacitors Ch1a to Ch1d. According to an embodiment, when the a-th pixel Pa1 is operated, each of the sixth transistor T16 and the 2-a-th capacitor Ch1a may be operated as one component of the a-th pixel Pa1.

The a-th pixel Pa1 according to an embodiment of the present disclosure may be referred to as having a 6T2C (six transistors and two capacitors) structure. However, this structure is an example. A circuit configuration of the a-th pixel Pa1 is not limited thereto, and may be provided in various ways according to an embodiment. For another example, the a-th pixel Pa1 may also have a 7T2C (seven transistors and two capacitors) structure.

The 1-a-th transistor T11a may generate a light-emitting current Ida provided to the a-th light-emitting element OLEDa based on a voltage between a 1-a-th node n11a and a 2-a-th node n12a, i.e., voltage stored in the 1-a-th capacitor Cst1a. According to an embodiment, the 1-a-th transistor T11a may be an N-type metal oxide semiconductor (NMOS) transistor. According to an embodiment, a gate terminal, which is a control terminal of the 1-a-th transistor T11a, may be connected to the 1-a-th node n11a, a first terminal of the 1-a-th transistor T11a may be connected to a fourth node n14, which is a common node cn1, and a second terminal of the 1-a-th transistor T11a may be connected to the 2-a-th node n12a. The 1-a-th transistor T11a may be referred to as the driving transistor for driving the a-th light-emitting element OLEDa by providing the light-emitting current Ida based on the voltage stored in the 1-a-th capacitor Cst1a.

In the present disclosure, the first terminal of the transistor may indicate a “drain terminal”, and the second terminal of the transistor may indicate a “source terminal”, and are not limited thereto.

The 2-a-th transistor T12a may connect the 1-a-th node n11a and the j-th data line DLj to each other based on an i−1-th scan signal GWi provided through an i-th data scan line GWLi of the i-th scan line SLi. According to an embodiment, the 2-a-th transistor T12a may transmit the data voltage of the j-th data line DLj based on the i−1-th scan signal GWi. According to an embodiment, the 2-a-th transistor T12a may be the NMOS transistor. According to an embodiment, the 2-a-th transistor T12a may include a gate terminal, which is a control terminal for receiving the i−1-th scan signal GWi, a first terminal connected to the j-th data line DLj, and a second terminal connected to the 1-a-th node n11a. The i−1-th scan signal GWi may be referred to as a data write signal, and the 2-a-th transistor T12a may be referred to as a scan transistor for transmitting the data voltage of the j-th data line DLj.

The 3-a-th transistor T13a may provide a first reference voltage Vref to the 1-a-th node n11a based on an i−2-th scan signal GRi provided through an i-th reset line GRLi of the i-th scan line SLi, thereby performing a reset operation on the 1-a-th node n11a. According to an embodiment, the 3-a-th transistor T13a may be the NMOS transistor. In an embodiment, the 3-a-th transistor T13a may include a gate terminal, which is a control terminal for receiving the i-2-th scan signal GRi, a first terminal for receiving the first reference voltage Vref, and a second terminal connected to the 1-a-th node n11a. The i−2-th scan signal GRi may be referred to as a reset signal, and the 3-a-th transistor T13a may be referred to as a reset transistor for applying the first reference voltage Vref to the 1-a-th node n11a.

The 4-a-th transistor T14a may provide an initialization voltage Vint to a 3-a-th node n13a based on an i−3-th scan signal GIi provided through an i-th initialization line GILi of the i-th scan line SLi, thereby perform an initialization operation on the 3-a-th node n13a. According to an embodiment, the 4-a-th transistor T14a may be the NMOS transistor. In an embodiment, the 4-a-th transistor T14a may include a gate terminal, which is a control terminal for receiving the i−3-th scan signal GIi, a first terminal connected to the 3-a-th node n13a, and a second terminal for receiving the initialization voltage Vint. The i−3-th scan signal GIi may be referred to as an initialization signal, and the 4-a-th transistor T14a may be referred to as an initialization transistor for applying the initialization voltage Vint to the 3-a-th node n13a connected to an anode AE of the a-th light-emitting element OLEDa.

The 5-a-th transistor T15a may connect the 2-a-th node n12a and the 3-a-th node n13a, connected to the anode AE of the a-th light-emitting element OLEDa, to each other based on an i-th light-emitting signal EMBi provided through the i-th light-emitting line Eli. According to an embodiment, the 5-a-th transistor T15a may be the NMOS transistor. In an embodiment, the 5-a-th transistor T15a may include a gate terminal, which is a control terminal for receiving the i-th light-emitting signal EMBi, a first terminal connected to the 2-a-th node n12a, and a second terminal connected to the anode AE of the a-th light-emitting element OLEDa. The i-th light-emitting signal EMBi may be referred to as a second light-emitting signal, and the 5-a-th transistor T15a may be referred to as a light-emitting transistor for providing a path of the light-emitting current Ida from a first power voltage line ELVDDL to a second power voltage line ELVSSL.

The 1-a-th capacitor Cst1a may be connected between the 1-a-th node n11a and the 2-a-th node n12a. The 1-a-th capacitor Cst1a may be referred to as a storage capacitor for storing the data voltage transmitted as the data signal from the j-th data line DLj through the 2-a-th transistor T12a. In an embodiment, the 1-a-th capacitor Cst1a may include a first electrode connected to the 1-a-th node n11a and a second electrode connected to the 2-a-th node n12a.

The a-th light-emitting element OLEDa may emit light based on the light-emitting current Ida generated by the 1-a-th transistor T11a. In an embodiment, the a-th light-emitting element OLEDa may be an organic light emitting diode (“OLED”), and is not limited thereto. In an embodiment, the a-th light-emitting element OLEDa may be any suitable light-emitting element. For example, the a-th light-emitting element OLEDa may be a nano light emitting diode (“NED”), a quantum dot (“QD”) light emitting diode, a micro light emitting diode, an inorganic light emitting diode, or any other suitable light-emitting element. In an embodiment, the a-th light-emitting element OLEDa may include the anode AE connected to the 3-a-th node n13a, and a cathode CE connected to the second power voltage line ELVSSL for providing a second power voltage ELVSS (for example, a low power voltage).

The sixth transistor T16 may connect the fourth node n14 and the first power voltage line ELVDDL to each other based on the k-th group light-emitting signal EMk provided through the k-th group light-emitting line GELk. According to an embodiment, the sixth transistor T16 may provide the first power voltage ELVDD to the fourth node n14, which is the common node cn1, based on the k-th group light-emitting signal EMk. According to an embodiment, the sixth transistor T16 may be the NMOS transistor. In an embodiment, the sixth transistor T16 may include a gate terminal, which is a control terminal for receiving the k-th group light-emitting signal EMk, a first terminal connected to the first power voltage line ELVDDL, which provides the first power voltage ELVDD, and a second terminal connected to the fourth node n14. The k-th group light-emitting signal EMk may be referred to as a first light-emitting signal, and the sixth transistor T16 may be referred to as a light-emitting transistor for providing a path of the light-emitting current Ida from the first power voltage line ELVDDL to the second power voltage line ELVSSL. The first power voltage line ELVDDL may actually be a portion of the connection line CNL in FIG. 4.

The 2-a-th capacitor Ch1a may be connected between the first power voltage line ELVDDL and the 2-a-th node n12a. The 2-a-th capacitor Ch1a may be referred to as a holding capacitor for maintaining a voltage at the 2-a-th node n12a. According to an embodiment, the 2-a-th capacitor Ch1a may include a first electrode connected to the first power voltage line ELVDDL and a second electrode connected to the 2-a-th node n12a. According to an embodiment, the 2-a-th capacitor Ch1a may be a parasitic capacitor disposed between the first power voltage line ELVDDL and the 2-a-th node n12a (or the second electrode of the 1-a-th capacitor Cst1a), and is not limited thereto.

In FIGS. 6 and 7, the 2-a-th capacitor Ch1a is shown as being entirely included in the common circuit CC1, which is provided for easy illustration in the drawings. The common circuit CC1 may actually include the first electrode of the 2-a-th capacitor Ch1a, and the a-th individual pixel circuit SPa may include the second electrode of the 2-a-th capacitor Ch1a. According to an embodiment, the first electrodes of the 2-a-th to 2-d-th capacitors Ch1a to Ch1d may be included in the common circuit CC1, and the first electrodes of the 2-a-th to 2-d-th capacitors Ch1a to Ch1d may be shared as one electrode.

In an embodiment, as shown in FIGS. 6 and 7, the 1-a-th to 5-a-th transistors T11a to T15a and the sixth transistor T16 may be the NMOS transistors, may be implemented as oxide transistors, and are not limited thereto. In an embodiment, some or all of the 1-a-th to 5-a-th transistors T11a to T15a and the sixth transistor T16 may be P-type metal oxide semiconductor (PMOS) transistors, and may be implemented as low-temperature polycrystalline silicon (“LTPS”) transistors.

The b-th individual pixel circuit SPb1 may include a 1-b-th transistor, a 2-b-th transistor, a 3-b-th transistor, a 4-b-th transistor, a 5-b-th transistor, a 1-b-th capacitor, and a b-th light-emitting element respectively corresponding to the 1-a-th transistor T11a, the 2-a-th transistor T12a, the 3-a-th transistor T13a, the 4-a-th transistor T14a, the 5-a-th transistor T15a, the 1-a-th capacitor Cst1a, and the a-th light-emitting element OLEDa.

The 2-b-th transistor, 3-b-th transistor, 4-b-th transistor, and 5-b-th transistor of the b-th individual pixel circuit SPb1 may be controlled by the i−1-th scan signal GWi provided through the i-th data scan line GWLi, the i−2-th scan signal GRi provided through the i-th reset line GRLi, the i−3-th scan signal GIi provided through the i-th initialization line GILi, and the i-th light-emitting signal EMBi provided through the i-th light-emitting line ELi. The 1-b-th transistor may generate the light-emitting current provided to the b-th light-emitting element based on a voltage stored in the 1-b-th capacitor on the basis of the data voltage provided through the j+1-th data line DLj+1. The b-th light-emitting element may emit light based on the light-emitting current generated by the 1-b-th transistor.

The c-th individual pixel circuit SPc1 may include a 1-c-th transistor, a 2-c-th transistor, a 3-c-th transistor, a 4-c-th transistor, a 5-c-th transistor, a 1-c-th capacitor, and a c-th light-emitting element respectively corresponding to the 1-a-th transistor T11a, the 2-a-th transistor T12a, the 3-a-th transistor T13a, the 4-a-th transistor T14a, the 5-a-th transistor T15a, the 1-a-th capacitor Cst1a, and the a-th light-emitting element OLEDa.

The 2-c-th transistor, 3-c-th transistor, 4-c-th transistor, and 5-c-th transistor of the c-th individual pixel circuit SPc1 may be controlled by an i+1-1-th scan signal GWi+1 provided through an i+1-th data scan line GWLi+1, an i+1-2-th scan signal GRi+1 provided through an i+1-th reset line GRLi+1, an i+1-3-th scan signal GIi+1 provided through an i+1-th initialization line GILi+1, and an i+1-th light-emitting signal EMBi+1 provided through the i+1-th light-emitting line ELi+1. The 1-c-th transistor may generate the light-emitting current provided to the c-th light-emitting element based on a voltage stored in the 1-c-th capacitor on the basis of the data voltage provided through the j-th data line DLj. The c-th light-emitting element may emit light based on the light-emitting current generated by the 1-c-th transistor.

The d-th individual pixel circuit SPd1 may include a 1-d-th transistor, a 2-d-th transistor, a 3-d-th transistor, a 4-d-th transistor, a 5-d-th transistor, a 1-d-th capacitor, and a d-th light-emitting element respectively corresponding to the 1-a-th transistor T11a, the 2-a-th transistor T12a, the 3-a-th transistor T13a, the 4-a-th transistor T14a, the 5-a-th transistor T15a, the 1-a-th capacitor Cst1a, and the a-th light-emitting element OLEDa.

The 2-d-th transistor, 3-d-th transistor, 4-d-th transistor, and 5-d-th transistor of the d-th individual pixel circuit SPd1 may be controlled by the i+1-th scan signal GWi+1 provided through the i+1-th data scan line GWLi+1, the i+1-2-th scan signal GRi+1 provided through the i+1-th reset line GRLi+1, the i+1-3-th scan signal GIi+1 provided through the i+1-th initialization line GILi+1, and the i+1-th light-emitting signal EMBi+1 provided through the i+1-th light-emitting line ELi+1. The 1-d-th transistor may generate the light-emitting current provided to the d-th light-emitting element based on a voltage stored in the 1-d-th capacitor on the basis of the data voltage provided through the j+1-th data line DLj+1. The d-th light-emitting element may emit light based on the light-emitting current generated by the 1-d-th transistor.

Each of the b-th to d-th individual pixel circuits SPb1 to SPd1 may include a capacitor corresponding to the 1-a-th capacitor Cst1a. The b-th individual pixel circuit SPb1 may include the 1-b-th capacitor corresponding to a 1-a-th capacitor Cst2a. A 1-b-th node connected to the first electrode of the 1-b-th capacitor may be electrically isolated from the fourth node n14, which is the common node cn1, through the 1-b-th capacitor during a compensation period.

The c-th individual pixel circuit SPc1 may include a 1-c-th capacitor corresponding to the 1-a-th capacitor Cst1a. A 1-c-th node connected to the first electrode of the 1-c-th capacitor may be electrically isolated from the fourth node n14, which is the common node cn1, through the 1-c-th capacitor during the compensation period.

The d-th individual pixel circuit SPd1 may include a 1-d-th capacitor corresponding to the 1-a-th capacitor Cst1a. A 1-d-th node connected to the first electrode of the 1-d-th capacitor may be electrically isolated from the fourth node n14, which is the common node cn1, through the 1-d-th capacitor during the compensation period.

Therefore, each pixel in the pixel group PG1 may perform the compensation operation on its driving transistor while sharing the common circuit CC1 through the circuit placement in the a-th to d-th individual pixel circuits SPa1 to SPd1 as described above.

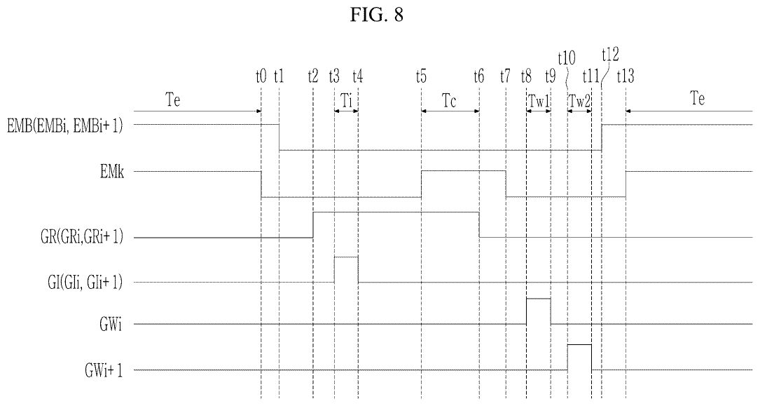

FIG. 8 is a timing diagram for explaining driving of the pixel in the display device according to an embodiment. Referring to FIG. 8, the description describes in detail operations of the plurality of pixels when the pixels connected to the i-th scan line SLi and the i+1-th scan line SLi+1, shown in FIGS. 5 to 7, are driven simultaneously in one frame period.

Referring to FIGS. 5 to 8, one frame period may include an initialization period Ti, a compensation period Tc, first and second data writing periods Tw1 and Tw2, and a light emission period Te.

Before a time point to, each of the k-th group light-emitting signal EMk, the i-th light-emitting signal EMBi, and the i+1-th light-emitting signal EMBi+1 may have a logic high level, thus turning on the sixth transistor T16 and the 5-a-th transistor T15a. Similarly, the 5-b-th to 5-d-th transistors of the b-th to d-th individual pixel circuits SPb1 to SPd1, corresponding to the 5-a-th transistor T15a, may be turned on. The a-th pixel Pa1 and the b-th to d-th pixels may perform the light-emitting operation during the light emission period Te based on the voltages respectively stored in the 1-a-th capacitor Cst1a and the 1-b-th to 1-d-th capacitors corresponding to the 1-a-th capacitor Cst1a before the time point to.

At the time point to, the k-th group light-emitting signal EMk may transition from the logic high level to a logic low level. The sixth transistor T16 may be turned off based on the k-th group light-emitting signal EMk.

At a time point t1, the i-th light-emitting signal EMBi and the i+1-th light-emitting signal EMBi+1 may transition from the logic high level to the logic low level. The 5-a-th transistor T15a may be turned off based on the i-th light-emitting signal EMBi. Similarly, the 5-b-th to 5-d-th transistors of the b-th to d-th individual pixel circuits SPb1 to SPd1, corresponding to the 5-a-th transistor T15a, may be turned off based on the i-th light-emitting signal EMBi and the i+1-th light-emitting signal EMBi+1.

At a time point t2, the i−2-th scan signal GRi and the i+1-2-th scan signal GRi+1 may transition from the logic low level to the logic high level. The 3-a-th transistor T13a may be turned on based on the i−2-th scan signal GRi. Similarly, the 3-b-th to 3-d-th transistors of the b-th to d-th individual pixel circuits SPb1 to SPd1, corresponding to the 3-a-th transistor T13a, may be turned on based on the i−2-th scan signal GRi and the i+1-2-th scan signal GRi+1. The first reference voltage Vref may be provided to the 1-a-th node n11a, and the 1-b-th to 1-d-th nodes of the b-th to d-th individual pixel circuits SPb1 to SPd1, corresponding to the 1-a-th node n11a, through the turn-on operations of the 3-a-th transistor T13a and the 3-b-th to 3-d-th transistors. The 1-a-th node n11a and the 1-b-th to the 1-d-th nodes may be reset to the first reference voltage Vref by the provision of the first reference voltage Vref.

At a time point t3, the i−3-th scan signal GIi and the i+1-3-th scan signal GIi+1 may transition from the logic low level to the logic high level. The 4-a-th transistor T14a may be turned on based on the i−3-th scan signal GIi. Similarly, the 4-b-th to 4-d-th transistors of the b-th to d-th individual pixel circuits SPb1 to SPd1, corresponding to the 4-a-th transistor T14a, may be turned on based on the i−3-th scan signal GIi and the i+1-3-th scan signal GIi+1. The initialization voltage Vint may be provided to the 3-a-th node n13a and the 3-b-th to 3-d-th nodes, corresponding to the 3-a-th node n13a, through the turn-on operations of the 4-a-th transistor T14a and the 4-b-th to 4-d-th transistors.

At a time point t4, the i−3-th scan signal GIi and the i+1-3-th scan signal GIi+1 may transition from the logic high level to the logic low level. The 4-a-th transistor T14a may be turned off based on the i−3-th scan signal GIi. Similarly, the 4-b-th to 4-d-th transistors may be turned off based on the i−3-th scan signal GIi and the i+1-3-th scan signal GIi+1.

During the initialization period Ti between the time point t3 and the time point t4, the initialization voltage Vint may be provided to the anodes AE of the a-th light-emitting element OLEDa and the b-th to d-th light-emitting elements of the b-th to d-th individual pixel circuits SPb1 to SPd that correspond to the a-th light-emitting element OLEDa. Accordingly, the anodes AE of the a-th light-emitting element OLEDa and the b-th to d-th light-emitting elements may be initialized based on the initialization voltage Vint. In addition, during the initialization period Ti, the 5-a-th transistor T15a and the 5-b-th to 5-d-th transistors of the b-th to d-th individual pixel circuits SPb1 to SPd1, corresponding to the 5-a-th transistor T15a, may be turned off to thus separate the 2-a-th node n12a and the 2-b-th to 2-d-th nodes of the b-th to d-th individual pixel circuits SPb1 to SPd1, corresponding to the 2-a-th node n12a, from the anodes AE of the a-th light-emitting element OLEDa and the b-th to d-th light-emitting elements.

At a time point t5, the k-th group light-emitting signal EMk may transition from the logic low level to the logic high level. The sixth transistor T16 may be turned on based on the k-th group light-emitting signal EMk.

At a time point t6, the i−2-th scan signal GRi and the i+1-2-th scan signal GRi+1 may transition from the logic high level to the logic low level. The 3-a-th transistor T13a and the 3-b-th to 3-d-th transistors, corresponding to the 3-a-th transistor T13a, may be turned off based on the i−2-th scan signal GRi and the i+1-2-th scan signal GRi+1.

During the compensation period Tc between the time point t5 and the time point t6, the sixth transistor T16 and the 3-a-th transistor T13a and the 3-b-th to 3-d-th transistors, corresponding to the 3-a-th transistor T13a, may be turned on. During the compensation period Tc, the first reference voltage Vref may be provided to the 1-a-th node n11a and the 1-b-th to 1-d-th nodes, corresponding to the 1-a-th node n11a, through the 3-a-th transistor T13a and the 3-b-th to 3-d-th transistors. During the compensation period Tc, the 1-a-th transistor T11a and the 1-b-th to 1-d-th transistors of the b-th to d-th individual pixel circuits SPb1 to SPd1, corresponding to the 1-a-th transistor T11, may be operated as source followers.

To describe the compensation operations on the 1-a-th transistor T11a and the 1-b-th to 1-d-th transistors by taking the a-th pixel Pa1 as an example, during the compensation period Tc, the 1-a-th transistor T11a may change the voltage at the 2-a-th node n12a to a voltage level close to the first reference voltage Vref at the 1-a-th node n11a. That is, the 1-a-th transistor T11a may be turned on to provide the current to the 2-a-th node n12a until a threshold voltage of the 1-a-th transistor T11a is stored in the 1-a-th capacitor Cst1a, that is, until the voltage at the 2-a-th node n12a reaches a voltage acquired by subtracting the threshold voltage from the first reference voltage Vref. In addition, during the compensation period Tc, the 5-a-th transistor T15a and the 5-b-th to 5-d-th transistors may be turned off to thus separate the 2-a-th node n12a and the 2-b-th to 2-d-th nodes from the anodes AE of the a-th light-emitting element OLEDa and the b-th to d-th light-emitting elements.

According to an embodiment, during the compensation operations in the compensation period Tc, the 1-a-th transistor T11a and the 1-b-th to 1-d-th transistors may be operated as the source followers. In addition, the fourth node n14, which is the common node cn1, may be electrically isolated from the 1-a-th node n11a and the 1-b-th to 1-d-th nodes of the a-th pixel Pa1 and the b-th to d-th pixels, through the arrangement of the 1-a-th capacitor Cst1a and the 1-b-th to 1-d-th capacitors during the compensation operations of the 1-a-th transistor T11a and the 1-b-th to 1-d-th transistors. The a-th pixel Pa1 and the b-th to d-th pixels may respectively perform the compensation operations on the 1-a-th transistor T11a and the 1-b-th to 1-d-th transistors while sharing the common circuit CC1, through the arrangement and operations of the 1-a-th transistor T11a, the 1-b-th to 1-d-th transistors, the 1-a-th capacitor Cst1a, and the 1-b-th to the 1-d-th capacitors.

At a time point t7, the k-th group light-emitting signal EMk may transition from the logic low level to the logic high level. The sixth transistor T16 may be turned off.

At a time point t8, the i−1-th scan signal GWi may transition from the logic low level to the logic high level. The 2-a-th transistor T12a and the 2-b-th transistor of the b-th individual pixel circuit SPb1, corresponding to the 2-a-th transistor T12a, may be turned on based on the i−1-th scan signal GWi. The 1-a-th node n11a and the j-th data line DLj may be connected to each other based on the turn-on operation of the 2-a-th transistor T12a, and the 1-b-th node and the j+1-th data line DLj+1 may be connected to each other based on the turn-on operation of the 2-b-th transistor.

At a time point t9, the i−1-th scan signal GWi may transition from the logic high level to the logic low level. The 2-a-th transistor T12a and the 2-b-th transistor may be turned off based on the i−1-th scan signal GWi.

The data voltage corresponding to a current to be provided to the a-th light-emitting element OLEDa may be provided to the 1-a-th node n11a through the j-th data line DLj, and the data voltage corresponding to a current to be provided to the b-th light-emitting element of the b-th individual pixel circuit SPb1, corresponding to the a-th light-emitting element OLEDa, may be provided to the 1-b-th node through the j+1-th data line DLj+1, through the turn-on operations of the 2-a-th transistor T12a and the 2-b-th transistor during the first data writing period Tw1 between the time point t8 and the time point t9.

During the first data writing period Tw1, the voltage at the 1-a-th node n11a may be changed from the first reference voltage Vref to the data voltage of the j-th data line DLj, and the 1-a-th capacitor Cst1a may store a voltage that reflects the threshold voltage of the 1-a-th transistor T11a based on the data voltage of the j-th data line DLj. Similarly, during the first data writing period Tw1, the voltage at the 1-b-th node may be changed from the first reference voltage Vref to the data voltage of the j+1-th data line DLj+1, and the 1-b-th capacitor may store a voltage that reflects a threshold voltage of the 1-b-th transistor based on the data voltage of the j+1-th data line DLj+1.

In addition, during the first data writing period Tw1, the 5-a-th transistor T15a and the 5-b-th transistor may be turned off to thus separate the 2-a-th node n12a and the second-b-th node from the anodes AE of the a-th light-emitting element OLEDa and the b-th light-emitting element.

At a time point t10, the i+1-1-th scan signal GWi+1 may transition from the logic low level to the logic high level. The 2-c-th and 2-d-th transistors of the c-th and d-th individual pixel circuits SPc1 and SPd1, corresponding to the 2-a-th transistor T12a, may be turned on based on the i+1-1-th scan signal GWi+1. The 1-c-th node and the j-th data line DLj may be connected to each other based on the turn-on operation of the 2-c-th transistor, and the 1-d-th node and the j+1-th data line DLj+1 may be connected to each other based on the turn-on operation of the 2-d-th transistor.

At a time point t11, the i+1-1-th scan signal GWi+1 may transition from the logic high level to the logic low level. The 2-c-th transistor and the 2-d-th transistor may be turned off based on the i+1-1-th scan signal GWi+1.

The data voltage corresponding to a current to be provided to the c-th light-emitting element of the c-th individual pixel circuit SPc1, corresponding to the a-th light-emitting element OLEDa, may be provided to the 1-c-th node through the j-th data line DLj, and the data voltage corresponding to a current to be provided to the d-th light-emitting element of the d-th individual pixel circuit SPd1, corresponding to the a-th light-emitting element OLEDa, may be provided to the 1-d-th node through the j+1-th data line DLj+1, through the turn-on operations of the 2-c-th transistor and the 2-d-th transistor during the second data writing period Tw2 between the time point t10 and the time point t11.

During the second data writing period Tw2, the voltage at the 1-c-th node may be changed from the first reference voltage Vref to the data voltage of the j-th data line DLj, and the 1-c-th capacitor may store a voltage that reflects a threshold voltage of the 1-c-th transistor based on the data voltage of the j-th data line DLj. Similarly, during the second data writing period Tw2, the voltage at the 1-d-th node may be changed from the first reference voltage Vref to the data voltage of the j+1-th data line DLj+1, and the 1-d-th capacitor may store a voltage that reflects a threshold voltage of the 1-d-th transistor based on the data voltage of the j+1-th data line DLj+1.

In addition, during the second data writing period Tw2, the 5-c-th transistor and the 5-d-th transistor may be turned off to thus separate the second-c-th node and the second-d-th node from the anodes AE of the c-th light-emitting element and the d-th light-emitting element.

At a time point t12, the i-th light-emitting signal EMBi and the i+1-th light-emitting signal EMBi+1 may transition from the logic low level to the logic high level. The 5-a-th transistor T15a and the 5-b-th to 5-d-th transistors may be turned on based on the i-th light-emitting signal EMBi and the i+1-th light-emitting signal EMBi+1.

At a time point t13, the k-th group light-emitting signal EMk may transition from the logic low level to the logic high level. The sixth transistor T16 may be turned on based on the k-th group light-emitting signal EMk.

The a-th pixel Pa1 and the b-th to d-th pixels may respectively provide paths of the light-emitting current for the a-th light-emitting element OLEDa and the b-th to d-th light-emitting elements through the turn-on operations of the 5-a-th transistor T15a, the 5-b-th to 5-d-th transistors, and the sixth transistor T16 during the light emission period Te after the time point t13. In addition, the 1-a-th transistor T11a and the 1-b-th to 1-d-th transistors may respectively be turned on based on the voltage stored between the 1-a-th capacitor Cst1a and the first and second electrodes of the 1-b-th to 1-d-th capacitors to thus respectively provide the light-emitting current to the light-emitting elements. The a-th light-emitting element OLEDa and the b-th to d-th light-emitting elements may respectively emit light based on the light-emitting current.

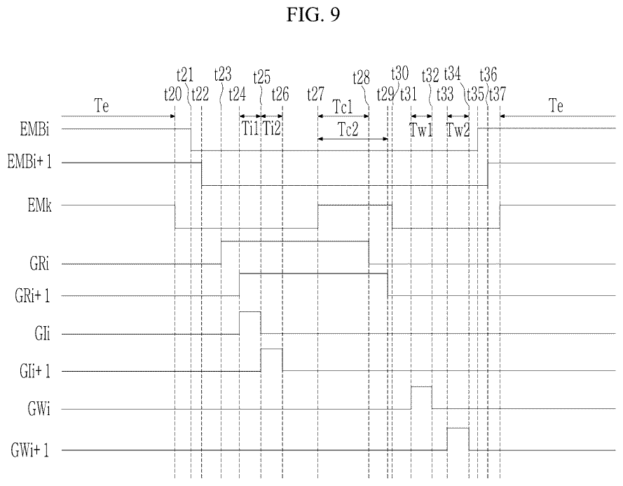

FIG. 9 is a timing diagram for explaining driving of the pixel in the display device according to an embodiment.

Referring to FIG. 9, the description describes in detail operations of the plurality of pixels when the pixels connected to the i-th scan line SLi and the i+1-th scan line SLi+1, shown in FIGS. 5 to 7, are driven simultaneously in one frame period.

In addition, first and second initialization periods Ti1 and Ti2 may correspond to the initialization period Ti of FIG. 8, first and second compensation periods Tc1 and Tc2 may correspond to the compensation period Tc of FIG. 8, first and second data writing periods Tw1 and Tw2 may correspond to the first and second data writing periods Tw1 and Tw2 of FIG. 8, and a light emission period Te may correspond to the light emission period Te of FIG. 8. For ease of description, an operation of the pixel group PG1 in FIG. 9 is described focusing on a difference from the description provided with reference to FIG. 8.

Referring to FIGS. 5 to 7 and 9, one frame period may include the first and second initialization periods Ti1 and Ti2, the first and second compensation periods Tc1 and Tc2, the first and second data writing periods Tw1 and Tw2, and the light emission period Te.

Before a time point t20, each of the k-th group light-emitting signal EMk, the i-th light-emitting signal EMBi, and the i+1-th light-emitting signal EMBi+1 may have the logic high level, thus turning on the sixth transistor T16 and the 5-a-th transistor T15a.

At the time point t20, the k-th group light-emitting signal EMk may transition from the logic high level to the logic low level. The sixth transistor T16 may be turned off based on the k-th group light-emitting signal EMk.

At a time point t21, the i-th light-emitting signal EMBi may transition from the logic high level to the logic low level. The 5-a-th transistor T15a and the 5-b-th transistor may be turned off based on the i-th light-emitting signal EMBi.

At a time point t22, the i+1-th light-emitting signal EMBi+1 may transition from the logic high level to the logic low level. The 5-c-th transistor and the 5-d-th transistor may be turned off based on the i+1-th light-emitting signal EMBi+1.

At a time point t23, the i−2-th scan signal GRi may transition from the logic low level to the logic high level. The 3-a-th transistor T13a and the 3-b-th transistor may be turned on based on the i−2-th scan signal GRi. The first reference voltage Vref may be provided to the 1-a-th node n11a and the 1-b-th node through the turn-on operations of the 3-a-th transistor T13a and the 3-b-th transistor. The 1-a-th node n11a and the 1-b-th node may be reset to the first reference voltage Vref by the provision of the first reference voltage Vref.

At a time point t24, the i+1-2-th scan signal GRi+1 may transition from the logic low level to the logic high level. The 3-c-th transistor and the 3-d-th transistor may be turned on based on the i+1-2-th scan signal GRi+1. The first reference voltage Vref may be provided to the 1-c-th node and the 1-d-th node through the turn-on operations of the 3-c-th transistor and the 3-d-th transistor. The 1-c-th node and the 1-d-th node may be reset to the first reference voltage Vref by the provision of the first reference voltage Vref.

At the time point t24, the i−3-th scan signal GIi may transition from the logic low level to the logic high level. The 4-a-th transistor T14a and the 4-b-th transistor may be turned on based on the i−3-th scan signal GIi. The initialization voltage Vint may be provided to the 3-a-th node n13a and the 3-b-th node through the turn-on operations of the 4-a-th transistor T14a and the 4-b-th transistor.

FIG. 9 shows that the i+1-2-th scan signal GRi+1 and the i−3-th scan signal GIi transition simultaneously to the logic high level. However, the present disclosure is not limited thereto, and the i+1-2-th scan signal GRi+1 and the i−3-th scan signal GIi may transition to the logic high level at different time points according to an embodiment.

At a time point t25, the i−3-th scan signal GIi may transition from the logic high level to the logic low level. The 4-a-th transistor T14a and the 4-b-th transistor may be turned off based on the i−3-th scan signal GIi.

During the first initialization period Ti1 between the time point t24 and the time point t25, the initialization voltage Vint may be provided to the anodes AE of the a-th light-emitting element OLEDa and the b-th light-emitting element. Accordingly, the anodes AE of the a-th light-emitting element OLEDa and the b-th light-emitting element may be initialized based on the initialization voltage Vint.

At a time point t25, the i+1-3-th scan signal GIi+1 may transition from the logic low level to the logic high level. The 4-c-th transistor and the 4-d-th transistor may be turned on based on the i+1-3-th scan signal GIi+1. The initialization voltage Vint may be provided to the 3-c-th node and the 3-d-th node through the turn-on operations of the 4-c-th transistor and the 4-d-th transistor. FIG. 9 shows that the logic level of the i−3-th scan signal GIi and the logic level of the i+1-3-th scan signal GIi+1 transition simultaneously at the time point t25. However, the present disclosure is not limited thereto, and the logic level of the i-3-th scan signal GIi and the logic level of the i+1-3-th scan signal GIi+1 may transition at different time points according to an embodiment.

At a time point t26, the i+1-3-th scan signal GIi+1 may transition from the logic high level to the logic low level. The 4-c-th transistor and the 4-d-th transistor may be turned off based on the i+1-3-th scan signal GIi+1.

During the second initialization period Ti2 between the time point t25 and the time point t26, the initialization voltage Vint may be provided to the anodes AE of the c-th light-emitting element and the d-th light-emitting element. Accordingly, the anodes AE of the c-th light-emitting element and the d-th light-emitting element may be initialized based on the initialization voltage Vint.

At a time point t27, the k-th group light-emitting signal EMk may transition from the logic low level to the logic high level. The sixth transistor T16 may be turned on based on the k-th group light-emitting signal EMk.

At a time point t28, the i−2-th scan signal GRi may transition from the logic high level to the logic low level. The 3-a-th transistor T13a and the 3-b-th transistor may be turned off based on the k-th group light-emitting signal EMk.

At a time point t29, the i+1-2-th scan signal GRi+1 may transition from the logic high level to the logic low level. The 3-c-th transistor and the 3-d-th transistor may be turned off based on the i+1-2-th scan signal GRi+1.

During the first compensation period Tc1 between the time point t27 and the time point t28, the sixth transistor T16, and the 3-a-th transistor T13a, and the 3-b-th transistor may be turned on. The compensation operations may be performed on the 1-a-th transistor T11a and the 1-b-th transistor through the turn-on operations of the sixth transistor T16, the 3-a-th transistor T13a, and the 3-b-th transistor. During the compensation operations, the 1-a-th transistor T11a and the 1-b-th transistor may be operated as the source followers. During the second compensation period Tc2 between the time point

t27 and the time point t29, the sixth transistor T16, the 3-a-th transistor T13a, and the 3-b-th transistor may be turned on. The compensation operations may be performed on the 1-c-th transistor and the 1-d-th transistor through the turn-on operations of the sixth transistor T16, the 3-c-th transistor, and the 3-d-th transistor. During the compensation operations, the 1-c-th transistor and the 1-d-th transistor may be operated as the source followers.

At a time point t30, the k-th group light-emitting signal EMk may transition from the logic high level to the logic low level. The sixth transistor T16 may be turned off based on the k-th group light-emitting signal EMk.

At a time point t31, the i−1-th scan signal GWi may transition from the logic low level to the logic high level. The 2-a-th transistor T12a and the 2-b-th transistor may be turned on based on the i−1-th scan signal GWi. The 1-a-th node n11a and the j-th data line DLj may be connected to each other based on the turn-on operation of the 2-a-th transistor T12a, and the 1-b-th node and the j+1-th data line DLj+1 may be connected to each other based on the turn-on operation of the 2-b-th transistor.

At a time point t32, the i−1-th scan signal GWi may transition from the logic high level to the logic low level. The 2-a-th transistor T12a and the 2-b-th transistor may be turned off based on the i−1-th scan signal GWi.

The data voltage corresponding to a current to be provided to the a-th light-emitting element OLEDa may be provided to the 1-a-th node n11a through the j-th data line DLj, and the data voltage corresponding to a current to be provided to the b-th light-emitting element may be provided to the 1-b-th node through the j+1-th data line DLj+1, through the turn-on operations of the 2-a-th transistor T12a and the 2-b-th transistor during the first data writing period Tw1 between the time point t31 and the time point t32.

At a time point t33, the i+1-1-th scan signal GWi+1 may transition from the logic low level to the logic high level. The 2-c-th transistor and the 2-d-th transistor may be turned on based on the i+1-1-th scan signal GWi+1. The 1-c-th node and the j-th data line DLj may be connected to each other based on the turn-on operation of the 2-c-th transistor, and the 1-d-th node and the j+1-th data line DLj+1 may be connected to each other based on the turn-on operation of the 2-d-th transistor.

At a time point t34, the i+1-1-th scan signal GWi+1 may transition from the logic high level to the logic low level. The 2-c-th transistor and the 2-d-th transistor may be turned off based on the i+1-1-th scan signal GWi+1.

The data voltage corresponding to a current to be provided to the c-th light-emitting element may be provided to the 1-c-th node through the j-th data line DLj, and the data voltage corresponding to a current to be provided to the d-th light-emitting element may be provided to the 1-d-th node through the j+1-th data line DLj+1, through the turn-on operations of the 2-c-th transistor and the 2-d-th transistor during the second data writing period Tw2 between the time point t33 and the time point t34.

At a time point t35, the i-th light-emitting signal EMBi may transition from the logic low level to the logic high level. The 5-a-th transistor T15a and the 5-b-th transistor may be turned on based on the i-th light-emitting signal EMBi.

At a time point t36, the i+1-th light-emitting signal EMBi+1 may transition from the logic low level to the logic high level. The 5-c-th transistor and the 5-d-th transistor may be turned on based on the i+1-th light-emitting signal EMBi+1.

At a time point t37, the k-th group light-emitting signal EMk may transition from the logic low level to the logic high level. The sixth transistor T16 may be turned on based on the k-th group light-emitting signal EMk.

The a-th pixel Pa1 and the b-th to d-th pixels may respectively provide the paths of the light-emitting current for the a-th light-emitting element OLEDa and the b-th to d-th light-emitting elements through the turn-on operations of the 5-a-th transistor T15a, the 5-b-th to 5-d-th transistors, and the sixth transistor T16 during the light emission period Te after the time point t37.

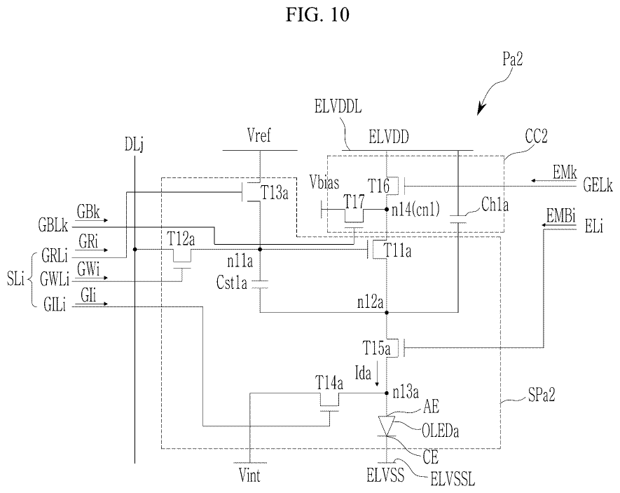

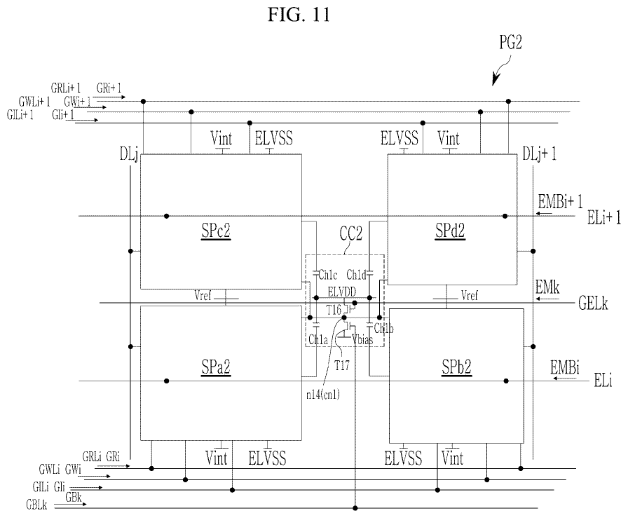

FIG. 10 is an equivalent circuit diagram of one pixel included in the display device according to an embodiment. FIG. 11 is a circuit diagram of a pixel group included in the display device according to an embodiment.

th to d-th individual pixel circuits SPa2 to SPd2, a common circuit CC2, an a-th pixel Pa2, and a pixel group PG2, shown in FIGS. 10 and 11, are respective examples of the a-th to d-th individual pixel circuits SPa to SPd, the common circuit CC, the a-th pixel Pa, and the pixel group PG, shown in FIG. 5. It is apparent that the descriptions of the a-th to d-th individual pixel circuits SPa to SPd, the common circuit CC, the a-th pixel Pa, and the pixel group PG, which are provided above with reference to FIG. 5, are applied to those of the a-th to d-th individual pixel circuits SPa2 to SPd2, the common circuit CC2, the a-th pixel Pa2, and the pixel group PG2.

In addition, the a-th to d-th individual pixel circuits SPa2 to SPd2, the common circuit CC2, the a-th pixel Pa2, and the pixel group PG2 may respectively correspond to the a-th to d-th individual pixel circuits SPa1 to SPd1, the common circuit CC1, the a-th pixel Pa1, and the pixel group PG1, shown in FIGS. 6 and 7. For ease of description, the a-th to d-th individual pixel circuits SPa2 to SPd2, the common circuit CC2, the a-th pixel Pa2, and the pixel group PG2 are described focusing on their differences from the a-th to d-th individual pixel circuits SPa1 to SPd1, the common circuit CC1, the a-th pixel Pa1, and the pixel group PG1, shown in FIGS. 6 and 7.

Referring to FIGS. 5, 6, 10, and 11, the common circuit CC2 may include the sixth transistor T16, a seventh transistor T17, and the 2-a-th to 2-d-th capacitors Ch1a to Ch1d. According to an embodiment, when the a-th pixel Pa2 is operated, each of the sixth transistor T16, the seventh transistor T17, and the 2-a-th capacitor Ch1a may be operated as one component of the a-th pixel Pa2.

The seventh transistor T17 may connect a second reference voltage Vbias to the fourth node n14 based on a k-th group initialization signal GBk provided through a k-th group initialization line GBLk. According to an embodiment, the seventh transistor T17 may provide the second reference voltage Vbias to the fourth node n14, which is the common node cn1, based on the k-th group initialization signal GBk. According to an embodiment, the seventh transistor T17 may be the NMOS transistor. In an embodiment, the seventh transistor T17 may include a gate terminal, which is a control terminal for receiving the k-th group initialization signal GBk, a first terminal for receiving the second reference voltage Vbias, and a second terminal connected to the fourth node n14. The k-th group initialization signal GBk may be referred to as the light-emitting initialization signal, and the seventh transistor T17 may be referred to as the light-emitting initialization transistor for performing the initialization operation on the fourth node n14, which is the common node cn1, before performing the light-emitting operation on the a-th light-emitting element OLEDa.

The k-th group initialization line GBLk may provide the scan signal for simultaneously controlling the plurality of pixels connected to the i-th light-emitting line ELi and the i+1-th light-emitting line ELi+1 adjacent to each other. The pixel group PG2 may receive the k-th group initialization signal GBk as the scan signal through the k-th group initialization line GBLk, and perform the initialization operation before the light-emitting operation. According to an embodiment, “k” may be the absolute value of the value acquired by dividing “i” in half.

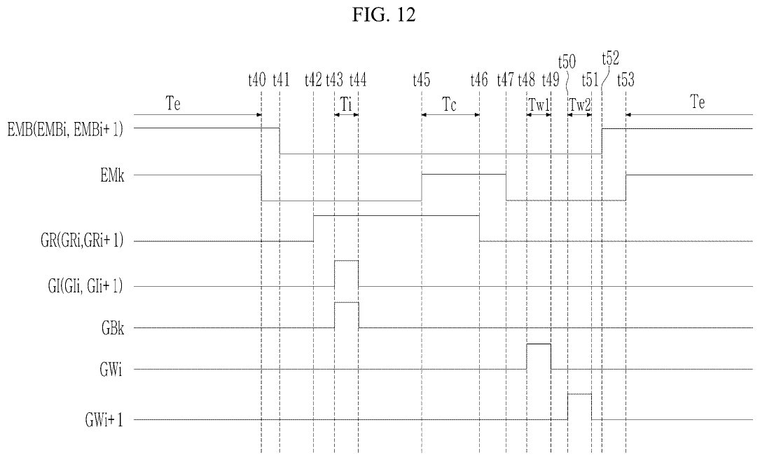

In an embodiment, as shown in FIGS. 10 and 11, the seventh transistor T17 may be the NMOS transistor, may be implemented as the oxide transistor, and is not limited thereto. In an embodiment, the seventh transistor T17 may be the PMOS transistor, or may be implemented as the LTPS transistor. FIG. 12 is a timing diagram for explaining driving of the pixel in the display device according to an embodiment. Referring to FIG. 12, the description describes in detail operations of the plurality of pixels when the pixels, connected to the i-th scan line SLi and the i+1-th scan line SLi+1, shown in FIGS. 10 to 11, are driven simultaneously in one frame period.

The initialization period Ti may correspond to the initialization period Ti of FIG. 8, the compensation period Tc may correspond to the compensation period Tc of FIG. 8, the first and second data writing periods Tw1 and Tw2 may correspond to the first and second data writing periods Tw1 and Tw2 of FIG. 8, and the light emission period Te may correspond to the light emission period Te of FIG. 8. For ease of description, an operation of the pixel group PG2 in FIG. 12 is described focusing on a difference from the description provided with reference to FIG. 8.

Referring to FIGS. 5, 6, and 10 to 12, one frame period may include the initialization period Ti, the compensation period Tc, the first and second data writing periods Tw1 and Tw2, and the light emission period Te.

Before a time point t40, each of the k-th group light-emitting signal EMk, the i-th light-emitting signal EMBi, and the i+1-th light-emitting signal EMBi+1 may have the logic high level, thus turning on the sixth transistor T16, the 5-a-th transistor T15a, and the 5-b-th to 5-d-th transistors. The a-th pixel Pa1, the b-th to d-th pixels may perform the light-emitting operations in the light emission period Te through the sixth transistor T16, the 5-a-th transistor T15a, and the 5-b-th to 5-d-th transistors.

At the time point t40, the k-th group light-emitting signal EMk may transition from the logic high level to the logic low level. The sixth transistor T16 may be turned off based on the k-th group light-emitting signal EMk.

At a time point t41, the i-th light-emitting signal EMBi and the i+1-th light-emitting signal EMBi+1 may transition from the logic high level to the logic low level. The 5-a-th transistor T15a and the 5-b-th to 5-d-th transistors may be turned off based on the i-th light-emitting signal EMBi and the i+1-th light-emitting signal EMBi+1.

At a time point t42, the i−2-th scan signal GRi and the i+1-2-th scan signal GRi+1 may transition from the logic low level to the logic high level. The 3-a-th transistor T13a and the 3-b-th to 3-d-th transistors may be turned on based on the i−2-th scan signal GRi and the i+1-2-th scan signal GRi+1.

At a time point t43, the i−3-th scan signal GIi, the i+1-3-th scan signal GIi+1, and the k-th group initialization signal GBk may transition from the logic low level to the logic high level. The 4-a-th transistor T14a, the 4-b-th to 4-d-th transistors, and the seventh transistor T17 may be turned on based on the i−3-th scan signal GIi, the i+1-3-th scan signal GIi+1, and the k-th group initialization signal GBk. The initialization voltage Vint may be provided to the 3-a-th node n13a and the 3-b-th to 3-d-th nodes, corresponding to the 3-a-th node n13a, through the turn-on operations of the 4-a-th transistor T14a and the 4-b-th to 4-d-th transistors. The second reference voltage Vbias may be provided to the fourth node n14, which is the common node cn1, through the turn-on operation of the seventh transistor T17.

At a time point t44, the i−3-th scan signal GIi, the i+1-3-th scan signal GIi+1, and the k-th group initialization signal GBk may transition from the logic high level to the logic low level. The 4-a-th transistor T14a, the 4-b-th to 4-d-th transistors, and the seventh transistor T17 may be turned off based on the i−3-th scan signal GIi, the i+1-3-th scan signal GIi+1, and the k-th group initialization signal GBk.

During the initialization period Ti between the time point t43 and the time point t44, the initialization operation may be performed on the anodes AE of the a-th light-emitting element OLEDa and the b-th to d-th light-emitting elements of the b-th to d-th individual pixel circuits SPb2 to SPd2 that correspond to the a-th light-emitting element OLEDa. In addition, the second reference voltage Vbias may be provided to the fourth node n14, which is the common node cn1. Accordingly, the fourth node n14 may be initialized to emit light based on the second reference voltage Vbias.

At a time point t45, the k-th group light-emitting signal EMk may transition from the logic low level to the logic high level. The sixth transistor T16 may be turned on based on the k-th group light-emitting signal EMk.

At a time point t46, the i−2-th scan signal GRi and the i+1-2-th scan signal GRi+1 may transition from the logic high level to the logic low level. The 3-a-th transistor T13a and the 3-b-th to 3-d-th transistors, corresponding to the 3-a-th transistor T13a, may be turned off based on the i−2-th scan signal GRi and the i+1-2-th scan signal GRi+1.

During the compensation period Tc between the time point t45 and the time point t46, the sixth transistor T16, the 3-a-th transistor T13a, and the 3-b-th to 3-d-th transistors, corresponding to the 3-a-th transistor T13a, may be turned on to thus perform the compensation operations on the 1-a-th transistor T11a, and the 1-b-th to 1-d-th transistors of the b-th to d-th individual pixel circuits SPb2 to SPd2. During the compensation period Tc, the 1-a-th transistor T11a and the 1-b-th to 1-d-th transistors may be operated as the source followers.

At the time point t47, the k-th group light-emitting signal EMk may transition from the logic high level to the logic low level. The sixth transistor T16 may be turned off.

At a time point t48, the i−1-th scan signal GWi may transition from the logic low level to the logic high level. The 2-a-th transistor T12a and the 2-b-th transistor of the b-th individual pixel circuit SPb2, corresponding to the 2-a-th transistor T12a, may be turned on based on the i−1-th scan signal GWi.

At a time point t49, the i−1-th scan signal GWi may transition from the logic high level to the logic low level. The 2-a-th transistor T12a and the 2-b-th transistor may be turned off based on the i−1-th scan signal GWi.

The data voltage corresponding to a current to be provided to the a-th light-emitting element OLEDa may be provided to the 1-a-th node n11a through the j-th data line DLj, and the data voltage corresponding to a current to be provided to the b-th light-emitting element of the b-th individual pixel circuit SPb2, corresponding to the a-th light-emitting element OLEDa, may be provided to the 1-b-th node through the j+1-th data line DLj+1, through the turn-on operations of the 2-a-th transistor T12a and the 2-b-th transistor during the first data writing period Tw1 between the time point t48 and the time point t49.

At a time point t50, the i+1-1-th scan signal GWi+1 may transition from the logic low level to the logic high level. The 2-c-th and 2-d-th transistors of the c-th and d-th individual pixel circuits SPc2 and SPd2, corresponding to the 2-a-th transistor T12a, may be turned on based on the i+1-1-th scan signal GWi+1.

The 1-c-th node and the j-th data line DLj may be connected to each other based on the turn-on operation of the 2-c-th transistor, and the 1-d-th node and the j+1-th data line DLj+1 may be connected to each other based on the turn-on operation of the 2-d-th transistor.

At a time point t51, the i+1-1-th scan signal GWi+1 may transition from the logic high level to the logic low level. The 2-c-th transistor and the 2-d-th transistor may be turned off based on the i+1-1-th scan signal GWi+1.

The data voltage corresponding to a current to be provided to the c-th light-emitting element of the c-th individual pixel circuit SPc2, corresponding to the a-th light-emitting element OLEDa, may be provided to the 1-c-th node through the j-th data line DLj, and the data voltage corresponding to a current to be provided to the d-th light-emitting element of the d-th individual pixel circuit SPd2, corresponding to the a-th light-emitting element OLEDa, may be provided to the 1-d-th node through the j+1-th data line DLj+1, through the turn-on operations of the 2-c-th transistor and the 2-d-th transistor during the second data writing period Tw2 between the time point t50 and the time point t51.

At a time point t52, the i-th light-emitting signal EMBi and the i+1-th light-emitting signal EMBi+1 may transition from the logic low level to the logic high level. The 5-a-th transistor T15a and the 5-b-th to 5-d-th transistors may be turned on based on the i-th light-emitting signal EMBi and the i+1-th light-emitting signal EMBi+1.

At a time point t53, the k-th group light-emitting signal EMk may transition from the logic low level to the logic high level. The sixth transistor T16 may be turned on based on the k-th group light-emitting signal EMk.

The a-th pixel Pa1 and the b-th to d-th pixels may respectively provide the paths of the light-emitting current for the a-th light-emitting element OLEDa and the b-th to d-th light-emitting elements through the turn-on operations of the 5-a-th transistor T15a, the 5-b-th to 5-d-th transistors, and the sixth transistor T16 during the light emission period Te after the time point t53. In addition, the 1-a-th transistor T11a and the 1-b-th to 1-d-th transistors may respectively be turned on based on the voltage stored between the 1-a-th capacitor Cst1a and the first and second electrodes of the 1-b-th to 1-d-th capacitors to thus respectively provide the light-emitting current to the light-emitting elements. The a-th light-emitting element OLEDa and the b-th to d-th light-emitting elements may respectively emit light based on the light-emitting current.

FIG. 12 shows in detail the operations of the plurality of pixels when the pixels connected to the i-th scan line SLi and the i+1-th scan line SLi+1 are driven simultaneously. However, the present disclosure is not limited thereto, and the operation of the pixel group PG2 may be driven for each scan line according to an embodiment.

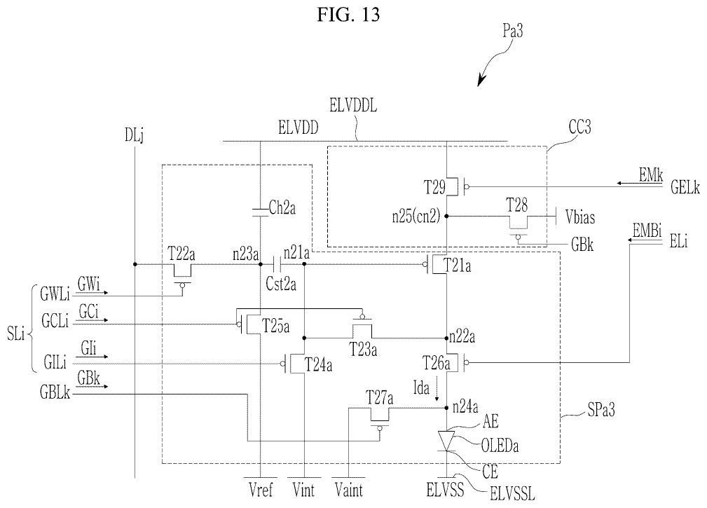

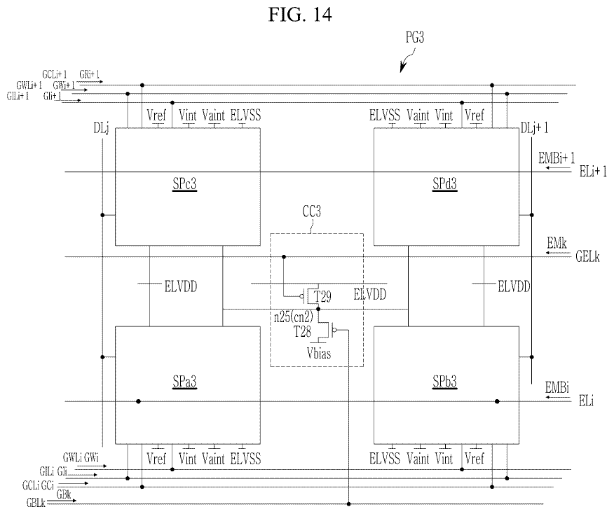

FIG. 13 is an equivalent circuit diagram of one pixel included in the display device according to an embodiment. FIG. 14 is a circuit diagram of a pixel group included in the display device according to an embodiment.

th to d-th individual pixel circuits Spa3 to SPd3, a common circuit CC3, an a-th pixel Pa3, and a pixel group PG3, shown in FIGS. 13 and 14, are respective examples of the a-th to d-th individual pixel circuits SPa to SPd, the common circuit CC, the a-th pixel Pa, and the pixel group PG, shown in FIG. 5. It is apparent that the descriptions of the a-th to d-th individual pixel circuits SPa to SPd, the common circuit CC, the a-th pixel Pa, and the pixel group PG, which are provided above with reference to FIG. 5, are applied to those of the a-th to d-th individual pixel circuits Spa3 to SPd3, the common circuit CC3, the a-th pixel Pa3, and the pixel group PG3.

Referring to FIGS. 5, 6, 13, and 14, the a-th pixel Pa3 may include the a-th individual pixel circuit SPa3 and share at least a portion of the common circuit CC3 with the b-th to d-th pixels. The a-th individual pixel circuit SPa3 may include a 1-a-th transistor T21a, a 2-a-th transistor T22a, a 3-a-th transistor T23a, a 4-a-th transistor T24a, a 5-a-th transistor T25a, a 6-a-th transistor T26a, a 7-a-th transistor T27a, the 1-a-th capacitor Cst2a, a 2-a-th capacitor Ch2a, and the a-th light-emitting element OLEDa.

The common circuit CC3 may include an eighth transistor T28 and a ninth transistor T29. According to an embodiment, when the a-th pixel Pa3 is operated, each of the eighth transistor T28 and the ninth transistor T29 may be operated as one component of the a-th pixel Pa3.

The a-th pixel Pa3 according to an embodiment of the present disclosure may be referred to as having a 9T2C (nine transistors and two capacitors) structure. However, this structure is an example. A circuit configuration of the a-th pixel Pa3 is not limited thereto, and may be provided in various ways according to an embodiment. For another example, the a-th pixel Pa3 may also have a 10T2C (ten transistors and two capacitors) structure.

The 1-a-th transistor T21a may generate the light-emitting current Ida provided to the a-th light-emitting element OLEDa based on a voltage between a 1-a-th node n21a and a fifth node n25, i.e., voltage at the 1-a-th node n21a connected to the first electrode of the 1-a-th capacitor Cst2a. According to an embodiment, the 1-a-th transistor T21a may be the PMOS transistor. According to an embodiment, a gate terminal, which is a control terminal of the 1-a-th transistor T21a, may be connected to the 1-a-th node n21a, a first terminal of the 1-a-th transistor T21a may be connected to a 2-a-th node n22a, and a second terminal of the 1-a-th transistor T21a may be connected to a fifth node n25, which is a common node cn2. The 1-a-th transistor T21a may be referred to as the driving transistor for driving the a-th light-emitting element OLEDa by providing the light-emitting current Ida based on the voltage at the 1-a-th node n21a connected to the first electrode of the 1-a-th capacitor Cst2a.

The 2-a-th transistor T22a may connect a 3-a-th node n23a and the j-th data line DLj to each other based on the i−1-th scan signal GWi provided through the i-th data scan line GWLi of the i-th scan line SLi. According to an embodiment, the 2-a-th transistor T22a may provide the data voltage of the j-th data line DLj based on the i−1-th scan signal GWi. According to an embodiment, the 2-a-th transistor T22a may be the PMOS transistor. According to an embodiment, the 2-a-th transistor T22a may include a gate terminal, which is a control terminal for receiving the i−1-th scan signal GWi, a first terminal connected to the 2-a-th node n22a, and a second terminal connected to the j-th data line DLj. The i−1-th scan signal GWi may be referred to as the data write signal, and the 2-a-th transistor T22a may be referred to as the scan transistor for transmitting the data voltage of the j-th data line DLj.

The 3-a-th transistor T23a may connect the 1-a-th node n21a and the 2-a-th node n22a to each other based on an i−2-th scan signal GCi provided through an i-th compensation line GCLi of the i-th scan line SLi. According to an embodiment, the 3-a-th transistor T23a may be the PMOS transistor. In an embodiment, the 3-a-th transistor T23a may include a gate terminal, which is a control terminal for receiving the i−2-th scan signal GCi, a first terminal connected to the 1-a-th node n21a, and a second terminal connected to the 2-a-th node n22a. The i−2-th scan signal GCi may be referred to as a compensation signal, and the 3-a-th transistor T23a may be referred to as a compensation transistor by connecting the first terminal and the gate terminal of the 1-a-th transistor T21a to each other when performing the compensation operation on the 1-a-th transistor T21a.

The 4-a-th transistor T24a may provide the initialization voltage Vint to the 1-a-th node n21a based on the i−3-th scan signal GIi provided through the i-th initialization line GILi of the i-th scan line SLi, thereby performing the initialization operation on the 1-a-th node n21a. According to an embodiment, the 4-a-th transistor T24a may be the PMOS transistor. In an embodiment, the 4-a-th transistor T24a may include a gate terminal, which is a control terminal for receiving the i−3-th scan signal GIi, a first terminal for receiving the initialization voltage Vint, and a second terminal connected to the 1-a-th node n21a. The i-3-th scan signal GIi may be referred to as the initialization signal, and the 4-a-th transistor T24a may be referred to as the initialization transistor for applying the initialization voltage Vint to the 1-a-th node n21a, which is connected to the control terminal of the 1-a-th transistor T21a.

The 5-a-th transistor T25a may provide the first reference voltage Vref to the 3-a-th node n23a based on the i−2-th scan signal GCi provided through the i-th compensation line GCLi of the i-th scan line SLi. According to an embodiment, the 5-a-th transistor T25a may be the PMOS transistor. In an embodiment, the 5-a-th transistor T25a may include a gate terminal, which is a control terminal for receiving the i−2-th scan signal GCi, a first terminal for receiving the first reference voltage Vref, and a second terminal connected to the 3-a-th node n23a. The 5-a-th transistor T25a may be referred to as the compensation transistor for maintaining the 3-a-th node n23a at the first reference voltage Vref when performing the compensation operation on the 1-a-th transistor T21a.

The 6-a-th transistor T26a may connect the 2-a-th node n22a to a 4-a-th node n24a connected to the anode AE of the a-th light-emitting element OLEDa based on the i-th light-emitting signal EMBi provided through the i-th light-emitting line Eli. According to an embodiment, the 6-a-th transistor T26a may be the PMOS transistor. In an embodiment, the 6-a-th transistor T26a may include a gate terminal, which is a control terminal for receiving the i-th light-emitting signal EMBi, a first terminal connected to the anode AE of the a-th light-emitting element OLEDa, and a second terminal connected to the 2-a-th node n22a. The i-th light-emitting signal EMBi may be referred to as the second light-emitting signal, and the 6-a-th transistor T26a may be referred to as the light-emitting transistor for providing a path of the light-emitting current Ida from the first power voltage line ELVDDL to the second power voltage line ELVSSL.

The 7-a-th transistor T27a may provide a light-emission initialization voltage Vaint to the 4-a-th node n24a based on the k-th group initialization signal GBk provided through the k-th group initialization line GBLk, thereby performing the initialization operation on the 4-a-th node n24a. According to an embodiment, the 7-a-th transistor T27a may be the PMOS transistor. In an embodiment, 7-a-th transistor T27a may include a gate terminal, which is a control terminal for receiving the k-th group initialization signal GBk, a first terminal for receiving the light-emission initialization voltage Vaint, and a second terminal connected to the 4-a-th node n24a. The k-th group initialization signal GBk may be referred to as a light-emission initialization signal, and the 7-a-th transistor T27a may be referred to as a light-emission initialization transistor for applying the light-emission initialization voltage Vaint to the 4-a-th node n24a, which is connected to the anode AE of the a-th light-emitting element OLEDa.

The 1-a-th capacitor Cst2a may be connected between the 1-a-th node n21a and the 3-a-th node n23a. The 1-a-th capacitor Cst2a may be referred to as a storage capacitor for storing the data voltage transmitted as the data signal from the j-th data line DLj through the 2-a-th transistor T22a. In an embodiment, the 1-a-th capacitor Cst2a may include a first electrode connected to the 1-a-th node n21a and a second electrode connected to the 3-a-th node n23a.

The 2-a-th capacitor Ch2a may be connected between the first power voltage line ELVDDL and the 3-a-th node n23a. The 2-a-th capacitor Ch2a may be referred to as a holding capacitor for maintaining a voltage at the 3-a-th node n23a. According to an embodiment, the 2-a-th capacitor Ch2a may include a first electrode connected to the first power voltage line ELVDDL, and a second electrode connected to the 3-a-th node n23a.

During the compensation period, the 3-a-th node n23a and the fifth node n25, which is the common node cn2, may be electrically isolated from each other through the arrangement of the 1-a-th capacitor Cst2a and the 2-a-th capacitor Ch2a.

The a-th light-emitting element OLEDa may emit light based on the light-emitting current Ida generated by the 1-a-th transistor T21a. In an embodiment, the a-th light-emitting element OLEDa may be the organic light emitting diode (OLED), and is not limited thereto. In an embodiment, the a-th light-emitting element OLEDa may be any suitable light-emitting element. For example, the a-th light-emitting element OLEDa may be the nano light emitting diode (NED), the quantum dot (QD) light emitting diode, the micro light emitting diode, the inorganic light emitting diode, or any other suitable light-emitting element. In an embodiment, the a-th light-emitting element OLEDa may include the anode AE connected to the 4-a-th node n24a, and the cathode CE connected to the second power voltage line ELVSSL for providing the second power voltage ELVSS (for example, the low power voltage).

The eighth transistor T28 may connect the second reference voltage Vbias to the fifth node n25 based on the k-th group initialization signal GBk. According to an embodiment, the eighth transistor T28 may provide the second reference voltage Vbias to the fifth node n25, which is the common node cn2, based on the k-th group initialization signal GBk. According to an embodiment, the eighth transistor T28 may be the PMOS transistor. In an embodiment, the eighth transistor T28 may include a gate terminal, which is a control terminal for receiving the k-th group initialization signal GBk, a first terminal for receiving the second reference voltage Vbias, and a second terminal connected to the fifth node n25. The eighth transistor T28 may be referred to as the light-emission initialization transistor for performing the initialization operation on the fifth node n25, which is the common node cn2, before performing the light-emitting operation on the a-th light-emitting element OLEDa.

The ninth transistor T29 may connect the fifth node n25 and the first power voltage line ELVDDL to each other based on the k-th group light-emitting signal EMk provided through the k-th group light-emitting line GELk. According to an embodiment, the ninth transistor T29 may provide the first power voltage ELVDD to the fifth node n25, which is the common node cn2, based on the k-th group light-emitting signal EMk. According to an embodiment, the ninth transistor T29 may be the NMOS transistor. In an embodiment, the ninth transistor T29 may include a gate terminal, which is a control terminal for receiving the k-th group light-emitting signal EMk, a first terminal connected to the fifth node n25, and a second terminal connected to the first power voltage line ELVDDL, which provides the first power voltage ELVDD. The k-th group light-emitting signal EMk may be referred to as the first light-emitting signal, and the ninth transistor T29 may be referred to as the light-emitting transistor for providing a path of the light-emitting current Ida from the first power voltage line ELVDDL to the second power voltage line ELVSSL. The first power voltage line ELVDDL may actually be a portion of the connection line CNL in FIG. 4.

FIG. 13 and FIG. 14 show that the gate terminal of the eighth transistor T28 is connected to the k-th group initialization line GBLk, is not limited thereto, and may be connected to one of the i+1-th scan lines SLi+1 according to an embodiment.

In an embodiment, as shown in FIG. 13 and FIG. 4, the 1-a-th to 7-a-th transistors T21a to T27a, and the eighth and ninth transistors T28 and T29 may be the PMOS transistors, may be implemented as the LTPS transistors, and are not limited thereto. Some or all of the 1-a-th to 7-a-th transistors T21a to T27a, and the eighth and ninth transistors T28 and T29 may be the NMOS transistors, may be implemented as the oxide transistors, and are not limited thereto.

The b-th individual pixel circuit SPb3 may include the 1-b-th transistor, the 2-b-th transistor, the 3-b-th transistor, the 4-b-th transistor, the 5-b-th transistor, a 6-b-th transistor, a 7-b-th transistor, the 1-b-th capacitor, the 2-b-th capacitor, and the b-th light-emitting elements respectively corresponding to the 1-a-th transistor T21a, the 2-a-th transistor T22a, the 3-a-th transistor T23a, the 4-a-th transistor T24a, the 5-a-th transistor T25a, the 6-a-th transistor T26a, the 7-a-th transistor T27a, the 1-a-th capacitor Cst2a, the 2-a-th capacitor Ch2a, and the a-th light-emitting element OLEDa.

The 2-b-th transistor, 3-b-th transistor, 5-b-th transistor, 4-b-th transistor, 6-b-th transistor, and 7-b-th transistor of the b-th individual pixel circuit SPb3 may be controlled by the i−1-th scan signal GWi provided through the i-th data scan line GWLi, the i−2-th scan signal GCi provided through the i-th compensation line GCLi, the i−3-th scan signal GIi provided through the i-th initialization line GILi, the k-th group initialization signal GBk provided through the k-th group initialization line GBLk, and the i-th light-emitting signal EMBi provided through the i-th light-emitting line ELi. The 1-b-th transistor may generate the light-emitting current provided to the b-th light-emitting element based on the voltage stored in the 1-b-th capacitor on the basis of the data voltage provided through the j+1-th data line DLj+1. The b-th light-emitting element may emit light based on the light-emitting current generated by the 1-b-th transistor.

The c-th individual pixel circuit SPc3 may include the 1-c-th transistor, the 2-c-th transistor, the 3-c-th transistor, the 4-c-th transistor, the 5-c-th transistor, a 6-c-th transistor, a 7-c-th transistor, the 1-c-th capacitor, the 2-c-th capacitor, and the c-th light-emitting elements respectively corresponding to the 1-a-th transistor T21a, the 2-a-th transistor T22a, the 3-a-th transistor T23a, the 4-a-th transistor T24a, the 5-a-th transistor T25a, the 6-a-th transistor T26a, the 7-a-th transistor T27a, the 1-a-th capacitor Cst2a, the 2-a-th capacitor Ch2a, and the a-th light-emitting element OLEDa.

The 2-c-th transistor, 3-c-th transistor, 5-c-th transistor, 4-c-th transistor, 6-c-th transistor, and 7-c-th transistor of the c-th individual pixel circuit SPc3 may be controlled by the i+1-1-th scan signal GWi+1 provided through the i+1-th data scan line GWLi+1, the i+1-2-th scan signal GCi+1 provided through an i+1-th compensation line GCLi+1, the i+1-3-th scan signal GIi+1 provided through the i+1-th initialization line GILi+1, the k-th group initialization signal GBk provided through the k-th group initialization line GBLk, and the i+1-th light-emitting signal EMBi+1 provided through the i+1-th light-emitting line ELi+1. The 1-c-th transistor may generate the light-emitting current provided to the c-th light-emitting element based on a voltage stored in the 1-c-th capacitor on the basis of the data voltage provided through the j-th data line DLj. The c-th light-emitting element may emit light based on the light-emitting current generated by the 1-c-th transistor.

The d-th individual pixel circuit SPd3 may include the 1-d-th transistor, the 2-d-th transistor, the 3-d-th transistor, the 4-d-th transistor, the 5-d-th transistor, a 6-d-th transistor, a 7-d-th transistor, the 1-d-th capacitor, the 2-d-th capacitor, and the d-th light-emitting elements respectively corresponding to the 1-a-th transistor T21a, the 2-a-th transistor T22a, the 3-a-th transistor T23a, the 4-a-th transistor T24a, the 5-a-th transistor T25a, the 6-a-th transistor T26a, the 7-a-th transistor T27a, the 1-a-th capacitor Cst2a, the 2-a-th capacitor Ch2a, and the a-th light-emitting element OLEDa.

The 2-d-th transistor, 3-d-th transistor, 5-d-th transistor, 4-d-th transistor, 6-d-th transistor, and 7-d-th transistor of the d-th individual pixel circuit SPd3 may be controlled by the i+1-1-th scan signal GWi+1 provided through the i+1-th data scan line GWLi+1, the i+1-2-th scan signal GCi+1 provided through the i+1-th compensation line GCLi+1, the i+1-3-th scan signal GIi+1 provided through the i+1-th initialization line GILi+1, the k-th group initialization signal GBk provided through the k-th group initialization line GBLk, and the i+1-th light-emitting signal EMBi+1 provided through the i+1-th light-emitting line ELi+1. The 1-d-th transistor may generate the light-emitting current provided to the d-th light-emitting element based on the voltage stored in the 1-d-th capacitor on the basis of the data voltage provided through the j+1-th data line DLj+1. The d-th light-emitting element may emit light based on the light-emitting current generated by the 1-d-th transistor.

Each of the b-th to d-th individual pixel circuits SPb3 to SPd3 may include the respective capacitors corresponding to the 1-a-th capacitor Cst2a and the 2-a-th capacitor Ch2a. The b-th individual pixel circuit SPb3 may include the 1-a-th capacitor Cst2a and the 1-b-th capacitor and the 2-b-th capacitor, corresponding to the 2-a-th capacitor Ch2a. The 3-b-th node between the 1-b-th capacitor and the 2-b-th capacitor may be electrically isolated from the fifth node n15, which is the common node cn2, through the 1-b-th capacitor and the 2-b-th capacitor during the compensation period.

The c-th individual pixel circuit SPc3 may include the 1-c-th capacitor and the 2-c-th capacitor corresponding to the 1-a-th capacitor Cst2a and the 2-a-th capacitor Ch2a. The 3-c-th node between the 1-c-th capacitor and the 2-c-th capacitor may be electrically isolated from the fifth node n15, which is the common node cn2, through the 1-c-th capacitor and the 2-c-th capacitor during the compensation period.

The d-th individual pixel circuit SPd3 may include the 1-d-th capacitor and the 2-d-th capacitor corresponding to the 1-a-th capacitor Cst2a and the 2-a-th capacitor Ch2a. The 3-d-th node between the 1-d-th capacitor and the 2-d-th capacitor may be electrically isolated from the fifth node n15, which is the common node cn2, through the 1-d-th capacitor and the 2-d-th capacitor during the compensation period.

Therefore, through the circuit placement in the a-th to d-th individual pixel circuits Spa3 to SPd3 as described above, each pixel in the pixel group PG3 may perform the compensation operation for its driving transistor while sharing the common circuit CC3.

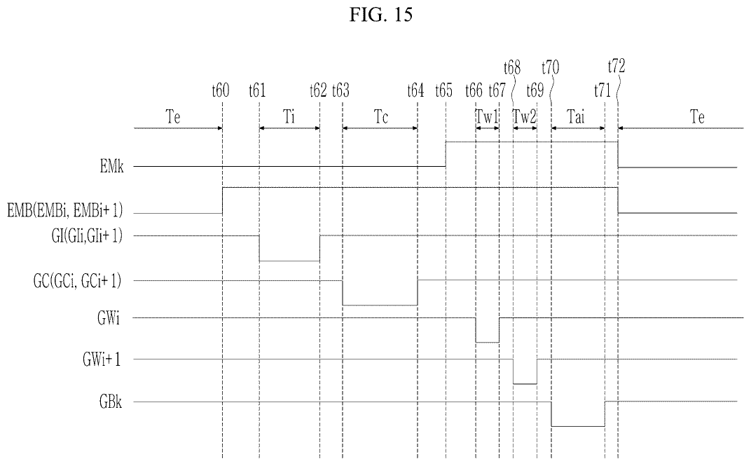

FIG. 15 is a timing diagram for explaining driving of the pixel in the display device according to an embodiment. Referring to FIG. 15, the description describes in detail operations of the plurality of pixels when the pixels, connected to the i-th scan line SLi and the i+1-th scan line SLi+1, shown in FIGS. 13 and 14, are driven simultaneously in one frame period.

Referring to FIGS. 5, 6, and 13 to 15, one frame period may include the initialization period Ti, the compensation period Tc, the data writing periods Tw1 and Tw2, and a light-emission initialization period Tai.

Before a time point t60, each of the k-th group light-emitting signal EMk, the i-th light-emitting signal EMBi, and the i+1-th light-emitting signal EMBi+1 may have the logic low level, thus turning on the ninth transistor T29 and the 6-a-th transistor T26a. Similarly, the 6-b-th to 6-d-th transistors of the b-th to d-th individual pixel circuits SPb3 to SPd3, corresponding to the 6-a-th transistor T26a, may be turned on. The a-th pixel Pa3, and the b-th to d-th pixels may perform the light-emitting operation during the light emission period Te based on the voltages respectively stored in the 1-a-th capacitor Cst2a and the 1-b-th to 1-d-th capacitors before the time point t60.

At the time point t60, the i-th light-emitting signal EMBi and the i+1-th light-emitting signal EMBi+1 may transition from the logic low level to the logic high level. The 6-a-th transistor T26a and the 6-b-th to 6-d-th transistors may be turned off based on the i-th light-emitting signal EMBi and the i+1-th light-emitting signal EMBi+1.

At a time point t61, the i−3-th scan signal GIi and the i+1-3-th scan signal GIi+1 may transition from the logic high level to the logic low level. The 4-a-th transistor T24a may be turned on based on the i−3-th scan signal GIi. Similarly, the 4-b-th to 4-d-th transistors of the b-th to d-th individual pixel circuits SPb3 to SPd3, corresponding to the 4-a-th transistor T24a, may be turned on based on the i−3-th scan signal GIi and the i+1-3-th scan signal GIi+1. The initialization voltage Vint may be provided to the 1-a-th node n21a and the 1-b-th to 1-d-th nodes, corresponding to the 1-a-th node n21a, through the turn-on operations of the 4-a-th transistor T24a and the 4-b-th to 4-d-th transistors.

At a time point t62, the i−3-th scan signal GIi and the i+1-3-th scan signal GIi+1 may transition from the logic low level to the logic high level. The 4-a-th transistor T24a may be turned off based on the i−3-th scan signal GIi. Similarly, the 4-b-th to 4-d-th transistors may be turned off based on the i−3-th scan signal GIi and the i+1-3-th scan signal GIi+1.

During the initialization period Ti between the time point t61 and the time point t62, the initialization voltage Vint may be provided to the 1-a-th node n21a and the 1-b-th to the 1-d-th nodes. Accordingly, the 1-a-th node n21a and the 1-b-th to 1-d-th nodes may be initialized based on the initialization voltage Vint.

At a time point t63, the i−2-th scan signal GCi and the i+1-2-th scan signal GCi+1 may transition from the logic high level to the logic low level. The 3-a-th transistor T23a and the 5-a-th transistor T25a may be turned on based on the i−2-th scan signal GCi. Similarly, the 3-b-th to 3-d-th transistors of the b-th to d-th individual pixel circuits SPb3 to SPd3, corresponding to the 3-a-th transistor T23a, and the 5-b-th to 5-d-th transistors of the b-th to d-th individual pixel circuits SPb3 to SPd3, corresponding to the 5-a-th transistor T25a, may be turned on based on the i−2-th scan signal GCi and the i+1-2-th scan signal GCi+1. The first reference voltage Vref may be provided to the 3-a-th node n23a and the 3-b-th to 3-d-th nodes through the turn-on operations of the 3-a-th transistor T23a and the 3-b-th to 3-d-th transistors. In addition, the control terminal and first terminal of the 1-a-th transistor T21a may be connected to each other through the turn-on operation of the 5-a-th transistor T25a, and similarly, the control terminals and first terminals of the 1-b-th to 1-d-th transistors may respectively be connected to each other through the turn-on operations of the 5-b-th to 5-d-th transistors.

At a time point t64, the i−2-th scan signal GCi and the i+1-2-th scan signal GCi+1 may transition from the logic low level to the logic high level. The 3-a-th transistor T23a and the 5-a-th transistor T25a may be turned off based on the i−2-th scan signal GCi. Similarly, the 3-b-th to 3-d-th transistors and the 5-b-th to 5-d-th transistors may be turned off based on the i−2-th scan signal GCi and the i+1-2-th scan signal GCi+1.

During the compensation period Tc between the time point t63 and the time point t64, the ninth transistor T29, the 3-a-th transistor T23a, the 3-b-th to 3-d-th transistors corresponding to the 3-a-th transistor T23a, the 5-a-th transistor T25a, and the 5-b-th to 5-d-th transistors corresponding to the 5-a-th transistor T25a may be turned on. The 1-a-th node n21a, the 1-b-th to 1-d-th nodes corresponding to the 1-a-th node n21a, the 2-a-th node n22a, and the 2-b-th to 2-d-th nodes corresponding to the 2-a-th node n22a may be connected to one another through the turn-on operations of the 3-a-th transistor T23a and the 3-b-th to 3-d-th transistors during the compensation period Tc. During the compensation period Tc, each of the 1-a-th transistor T21a and the 1-b-th to 1-d-th transistors of the b-th to d-th individual pixel circuits SPb3 to SPd3, corresponding to the 1-a-th transistor T21a, may be operated as the diode.

To describe the compensation operations on the 1-a-th transistor T21a and the 1-b-th to 1-d-th transistors by taking the a-th pixel Pa3 as an example, during the compensation period Tc, the 1-a-th transistor T21a may be operated as the diode to thus allow the current to flow toward the fifth node n25, which is the common node cn2, the 2-a-th node n22a, and the 1-a-th node n21a, thereby changing the voltage at the 1-a-th node n21a. The 1-a-th transistor T21a may be turned on to provide the current to the 1-a-th node n21a until the voltage at the 1-a-th node n21a reaches a voltage acquired by subtracting a threshold voltage of the 1-a-th transistor T21a from the first power voltage ELVDD. In addition, the voltage at the 3-a-th node n23a may be maintained at the first reference voltage Vref during the compensation period Tc, and the 1-a-th capacitor Cst2a may store a voltage that reflects the threshold voltage of the 1-a-th transistor T21a based on the first reference voltage Vref.

According to an embodiment, during the compensation period Tc, the 1-a-th transistor T21a and the 1-b-th to 1-d-th transistors may be operated as the diodes. In addition, during the compensation operations of the 1-a-th transistor T21a and the 1-b-th to 1-d-th transistors, the fifth node n25, which is the common node cn2, may be electrically isolated from the 3-a-th node n23a and the 3-b-th to 3-d-th nodes of the a-th pixel Pa3 and the b-th to d-th pixels through the arrangement of the 1-a-th capacitor Cst2a and the 1-b-th to 1-d-th capacitors. The a-th pixel Pa3 and the b-th to d-th pixels may respectively perform the compensation operations on the 1-a-th transistor T21a and the 1-b-th to 1-d-th transistors while sharing the common circuit CC3, through the arrangement and operations of the 1-a-th transistor T21a, the 1-b-th to 1-d-th transistors, the 1-a-th capacitor Cst2a, and the 1-b-th to the 1-d-th capacitors.

At a time point t65, the k-th group light-emitting signal EMk may transition from the logic low level to the logic high level. The ninth transistor T29 may be turned off.

At a time point t66, the i−1-th scan signal GWi may transition from the logic high level to the logic low level. The 2-a-th transistor T22a and the 2-b-th transistor of the b-th individual pixel circuit SPb3, corresponding to the 2-a-th transistor T22a, may be turned on based on the i−1-th scan signal GWi. The 3-a-th node n23a and the j-th data line DLj may be connected to each other based on the turn-on operation of the 2-a-th transistor T22a, and the 1-b-th node and the j+1-th data line DLj+1 may be connected to each other based on the turn-on operation of the 2-b-th transistor.

At a time point t67, the i−1-th scan signal GWi may transition from the logic low level to the logic high level. The 2-a-th transistor T22a and the 2-b-th transistor may be turned off based on the i−1-th scan signal GWi.

The data voltage corresponding to a current to be provided to the a-th light-emitting element OLEDa may be provided to the 3-a-th node n23a through the j-th data line DLj, and the data voltage corresponding to a current to be provided to the b-th light-emitting element of the b-th individual pixel circuit SPb3, corresponding to the a-th light-emitting element OLEDa, may be provided to the 3-b-th node through the j+1-th data line DLj+1, through the turn-on operations of the 2-a-th transistor T22a and the 2-b-th transistor during the first data writing period Tw1 between the time point t66 and the time point t67.

During the first data writing period Tw1, the voltage at the 3-a-th node n23a may be changed from the first reference voltage Vref to the data voltage of the j-th data line DLj, and the 1-a-th capacitor Cst2a may store a voltage that reflects the threshold voltage of the 1-a-th transistor T21a based on the data voltage of the j-th data line DLj. Similarly, during the first data writing period Tw1, the voltage at the 3-b-th node may be changed from the first reference voltage Vref to the data voltage of the j+1-th data line DLj+1, and the 1-b-th capacitor may store the voltage that reflects the threshold voltage of the 1-b-th transistor based on the data voltage of the j+1-th data line DLj+1.

At a time point t68, the i+1-1-th scan signal GWi+1 may transition from the logic high level to the logic low level. The 2-c-th and 2-d-th transistors of the c-th and d-th individual pixel circuits SPc3 and SPd3, corresponding to the 2-a-th transistor T22a, may be turned on based on the i+1-1-th scan signal GWi+1. The 3-c-th node and the j-th data line DLj may be connected to each other based on the turn-on operation of the 2-c-th transistor, and the 3-d-th node and the j+1-th data line DLj+1 may be connected to each other based on the turn-on operation of the 2-d-th transistor.

At a time point t69, the i+1-1-th scan signal GWi+1 may transition from the logic high level to the logic low level. The 2-c-th transistor and the 2-d-th transistor may be turned off based on the i+1-1-th scan signal GWi+1.

The data voltage corresponding to a current to be provided to the c-th light-emitting element of the c-th individual pixel circuit SPc3, corresponding to the a-th light-emitting element OLEDa, may be provided to the 3-c-th node through the j-th data line DLj, and the data voltage corresponding to a current to be provided to the d-th light-emitting element of the d-th individual pixel circuit SPd3, corresponding to the a-th light-emitting element OLEDa, may be provided to the 3-d-th node through the j+1-th data line DLj+1, through the turn-on operations of the 2-c-th transistor and the 2-d-th transistor during the second data writing period Tw2 between the time point t68 and the time point t69.

During the second data writing period Tw2, the voltage at the 3-c-th node may be changed from the first reference voltage Vref to the data voltage of the j-th data line DLj, and the 1-c-th capacitor may store the voltage that reflects the threshold voltage of the 1-c-th transistor based on the data voltage of the j-th data line DLj. Similarly, during the second data writing period Tw2, the voltage at the 1-d-th node may be changed from the first reference voltage Vref to the data voltage of the j+1-th data line DLj+1, and the 1-d-th capacitor may store the voltage that reflects the threshold voltage of the 1-d-th transistor based on the data voltage of the j+1-th data line DLj+1.

At a time point t70, the k-th group initialization signal GBk may transition from the logic high level to the logic low level. The 7-a-th transistor T27a, the 7-b-th to the 7-d-th transistors of the b-th to d-th individual pixel circuits SPb3 to SPd3, corresponding to the 7-a-th transistor T27a, and the eighth transistor T28 may be turned on based on the k-th group initialization signal GBk. The light-emission initialization voltage Vaint may be provided to the 4-a-th node n24a and the 4-b-th to 4-d-th nodes, corresponding to the 4-a-th node n24a, through the turn-on operations of the 7-a-th transistor T27a and the 7-b-th to 7-d-th transistors. The second reference voltage Vbias may be provided to the fifth node n25, which is the common node cn2, through the turn-on operation of the eighth transistor T28.

At a time point t71, the k-th group initialization signal GBk may transition from the logic low level to the logic high level. The 7-a-th transistor T27a, the 7-b-th to 7-d-th transistors, and the eighth transistor T28 may be turned off based on the k-th group initialization signal GBk.

During the light-emission initialization period Tai between the time point t70 and the time point t71, the initialization operation may be performed before performing light-emitting operation on the anodes AE of the a-th light-emitting element OLEDa and the b-th to d-th light-emitting elements of the b-th to d-th individual pixel circuits SPb3 to SPd3 that correspond to the a-th light-emitting element OLEDa. In addition, the second reference voltage Vbias may be provided to the fifth node n25, which is the common node cn2. Accordingly, the fifth node n25 may be initialized to emit light based on the second reference voltage Vbias.

At a time point t72, the k-th group light-emitting signal EMk, the i-th light-emitting signal EMBi, and the i+1-th light-emitting signal EMBi+1 may transition from the logic high level to the logic low level. The ninth transistor T29 may be turned on based on the k-th group light-emitting signal EMk. The 6-a-th transistor T26a and the 6-b-th to 6-d-th transistors may be turned on based on the i-th light-emitting signal EMBi and the i+1-th light-emitting signal EMBi+1.

FIG. 15 shows that the k-th group light-emitting signal EMk and the i-th light-emitting signal EMBi transition simultaneously to the logic low level. However, the present disclosure is not limited thereto, and the k-th group light-emitting signal EMk and the i-th light-emitting signal EMBi may transition to the logic low level at different time points according to an embodiment.

The a-th pixel Pa3 and the b-th to d-th pixels may respectively provide paths of the light-emitting current for the a-th light-emitting element OLEDa and the b-th to d-th light-emitting elements through the turn-on operations of the ninth transistor T29, the 6-a-th transistor T26a, and the 6-b-th to 6-d-th transistors during the light emission period Te after the time point t72. In addition, the 1-a-th transistor T21a and the 1-b-th to 1-d-th transistors may respectively be turned on based on the voltage at the 1-a-th node n21a and the 1-b-th to 1-d-th nodes, stored in the 1-a-th capacitor Cst1a and the 1-b-th to 1-d-th capacitors to thus respectively provide the light-emitting current to the light-emitting elements. The a-th light-emitting element OLEDa and the b-th to d-th light-emitting elements may respectively emit light based on the light-emitting current.

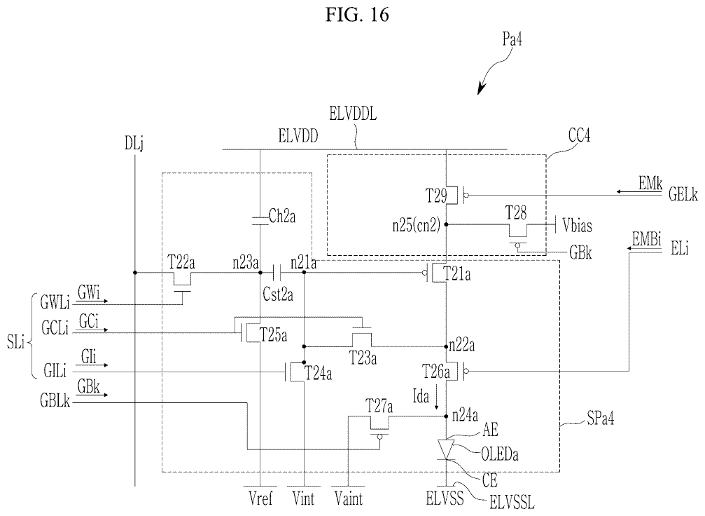

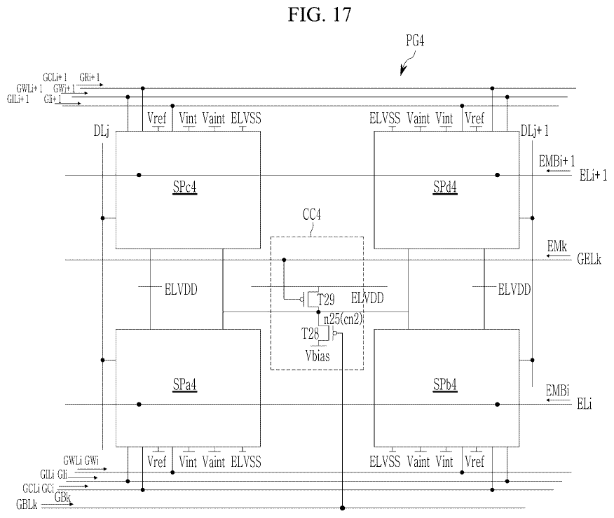

FIG. 16 is an equivalent circuit diagram of one pixel included in the display device according to an embodiment. FIG. 17 is a circuit diagram of a pixel group included in the display device according to an embodiment.

th to d-th individual pixel circuits SPa4 to SPd4, a common circuit CC4, an a-th pixel Pa4, and a pixel group PG4, shown in FIGS. 16 and 17, are respective examples of the a-th to d-th individual pixel circuits SPa to SPd, the common circuit CC, the a-th pixel Pa, and the pixel group PG, shown in FIG. 5. It is apparent that the descriptions of the a-th to d-th individual pixel circuits SPa to SPd, the common circuit CC, the a-th pixel Pa, and the pixel group PG, which are provided above with reference to FIG. 5, are applied to those of the a-th to d-th individual pixel circuits SPa4 to SPd4, the common circuit CC4, the a-th pixel Pa4, and the pixel group PG4.

In addition, the a-th to d-th individual pixel circuits SPa4 to SPd4, the common circuit CC4, the a-th pixel Pa4, and the pixel group PG4 may respectively correspond to the a-th to d-th individual pixel circuits SPa3 to SPd3, the common circuit CC3, the a-th pixel Pa3, and the pixel group PG3, shown in FIGS. 13 and 14. For ease of description, the a-th to d-th individual pixel circuits SPa4 to SPd4, the common circuit CC4, the a-th pixel Pa4, and the pixel group PG4 are described focusing on their differences from the a-th to d-th individual pixel circuits SPa3 to SPd3, the common circuit CC3, the a-th pixel Pa3, and the pixel group PG3, shown in FIGS. 13 and 14.

Referring to FIGS. 5, 6, 15, and 16, similar to the a-th individual pixel circuit SPa3 of FIG. 13, the a-th individual pixel circuit SPa4 may include the 1-a-th transistor T21a, the 2-a-th transistor T22a, the 3-a-th transistor T23a, the 4-a-th transistor T24a, the 5-a-th transistor T25a, the 6-a-th transistor T26a, the 7-a-th transistor T27a, the 1-a-th capacitor Cst2a, the 2-a-th capacitor Ch2a, and the a-th light-emitting element OLEDa.

The 2-a-th transistor T22a may be the NMOS transistor. According to an embodiment, the 2-a-th transistor T22a may include a gate terminal, which is a control terminal for receiving the i−1-th scan signal GWi, a first terminal connected to the j-th data line DLj, and a second terminal connected to the 2-a-th node n22a.

The 3-a-th transistor T23a may be the NMOS transistor. In an embodiment, the 3-a-th transistor T23a may include a gate terminal, which is a control terminal for receiving the i−2-th scan signal GCi, a first terminal connected to the 2-a-th node n22a, and a second terminal connected to the 1-a-th node n21a.

The 4-a-th transistor T24a may be the NMOS transistor. In an embodiment, the 4-a-th transistor T24a may include a gate terminal, which is a control terminal for receiving the i−3-th scan signal GIi, a first terminal connected to the 1-a-th node n21a, and a second terminal for receiving the initialization voltage Vint.

The 5-a-th transistor T25a may be the NMOS transistor. In an embodiment, the 5-a-th transistor T25a may include a gate terminal, which is a control terminal for receiving the i−2-th scan signal GCi, a first terminal connected to the 3-a-th node n23a, and a second terminal connected to the first reference voltage Vref.

As shown in FIG. 16 and FIG. 17, the 2-a-th to 5-a-th transistors T22a to T25a may be the NMOS transistors, and may be implemented as the oxide transistors.

Similar to the a-th individual pixel circuit SPa4, the b-th individual pixel circuit SPb4 may include the 1-b-th transistor, the 2-b-th transistor, and the 3-b-th transistor, the 4-b-th transistor, the 5-b-th transistor, the 6-b-th transistor, the 7-b-th transistor, the 1-b-th capacitor, the 2-b-th capacitor, and the b-th light-emitting elements.

The 2-b-th transistor, the 3-b-th transistor, the 4-b-th transistor, and the 5-b-th transistor may respectively correspond to the 2-a-th transistor T22a, the 3-a-th transistor T23a, the 4-a-th transistor T24a, and the 5-a-th transistor T25a, may be the NMOS transistors, and may be implemented as the oxide transistors.

Similar to the a-th individual pixel circuit SPa4, the c-th individual pixel circuit SPc4 may include the 1-c-th transistor, the 2-c-th transistor, and the 3-c-th transistor, the 4-c-th transistor, the 5-c-th transistor, the 6-c-th transistor, the 7-c-th transistor, the 1-c-th capacitor, the 2-c-th capacitor, and the c-th light-emitting elements.

The 2-c-th transistor, the 3-c-th transistor, the 4-c-th transistor, and the 5-c-th transistor may respectively correspond to the 2-a-th transistor T22a, the 3-a-th transistor T23a, the 4-a-th transistor T24a, and the 5-a-th transistor T25a, may be the NMOS transistors, and may be implemented as the oxide transistors.

Similar to the a-th individual pixel circuit SPa4, the d-th individual pixel circuit SPd4 may include the 1-d-th transistor, the 2-d-th transistor, and the 3-d-th transistor, the 4-d-th transistor, the 5-d-th transistor, the 6-d-th transistor, the 7-d-th transistor, the 1-d-th capacitor, the 2-d-th capacitor, and the d-th light-emitting elements.

The 2-d-th transistor, the 3-d-th transistor, the 4-d-th transistor, and the 5-d-th transistor may respectively correspond to the 2-a-th transistor T22a, the 3-a-th transistor T23a, the 4-a-th transistor T24a, and the 5-a-th transistor T25a, may be the NMOS transistors, and may be implemented as the oxide transistors.

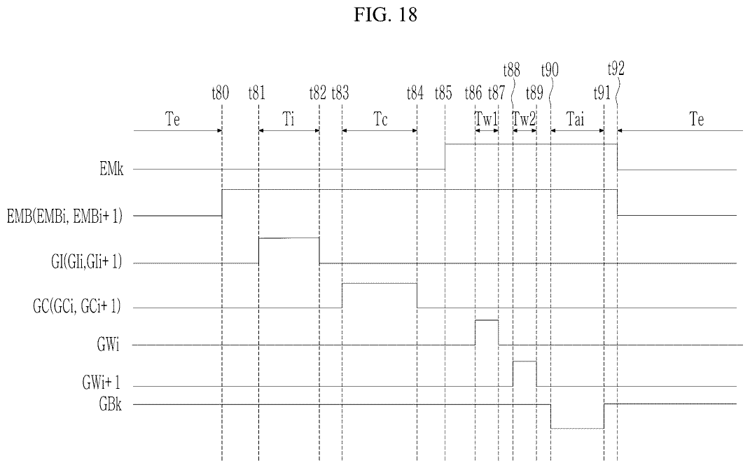

FIG. 18 is a timing diagram for explaining driving of the pixel in the display device according to an embodiment. Referring to FIG. 18, the description describes in detail operations of the plurality of pixels when the pixels, connected to the i-th scan line SLi and the i+1-th scan line SLi+1, shown in FIGS. 16 to 17, are driven simultaneously in one frame period.

The initialization period Ti may correspond to the initialization period Ti of FIG. 15, the compensation period Tc may correspond to the compensation period Tc of FIG. 15, the first and second data writing periods Tw1 and Tw2 may correspond to the first and second data writing periods Tw1 and Tw2 of FIG. 15, and the light emission period Te may correspond to the light emission period Te of FIG. 15. For ease of description, an operation of the pixel group PG4 in FIG. 18 is described focusing on a difference from the description provided with reference to FIG. 15.

Before a time point t80, each of the k-th group light-emitting signal EMk, the i-th light-emitting signal EMBi, and the i+1-th light-emitting signal EMBi+1 may have the logic low level, thus turning on the ninth transistor T29, the 6-a-th transistor T26a, and the 6-b-th to 6-d-th transistors. The a-th pixel Pa3, the b-th to d-th pixels may perform the light-emitting operations during the light emission period Te through the ninth transistor T29, the 6-a-th transistor T26a, and the 6-b-th to 6-d-th transistors.

At the time point t80, the i-th light-emitting signal EMBi and the i+1-th light-emitting signal EMBi+1 may transition from the logic low level to the logic high level. The 6-a-th transistor T26a and the 6-b-th to 6-d-th transistors may be turned off based on the i-th light-emitting signal EMBi and the i+1-th light-emitting signal EMBi+1.

At a time point t81, the i−3-th scan signal GIi and the i+1-3-th scan signal GIi+1 may transition from the logic low level to the logic high level. The 4-a-th transistor T24a and the 4-b-th to 4-d-th transistors may be turned on based on the i−3-th scan signal GIi and the i+1-3-th scan signal GIi+1. The initialization voltage Vint may be provided to the 1-a-th node n21a and the 1-b-th to 1-d-th nodes, corresponding to the 1-a-th node n21a, through the turn-on operations of the 4-a-th transistor T24a and the 4-b-th to 4-d-th transistors.

At a time point t82, the i−3-th scan signal GIi and the i+1-3-th scan signal GIi+1 may transition from the logic high level to the logic low level. The 4-a-th transistor T24a and the 4-b-th to 4-d-th transistors may be turned off based on the i−3-th scan signal GIi and the i+1-3-th scan signal GIi+1.

During the initialization period Ti between the time point t81 and the time point t82, the initialization voltage Vint may be provided to the 1-a-th node n21a and the 1-b-th to the 1-d-th nodes. Accordingly, the 1-a-th node n21a and the 1-b-th to 1-d-th nodes may be initialized based on the initialization voltage Vint.

At a time point t83, the i−2-th scan signal GCi and the i+1-2-th scan signal GCi+1 may transition from the logic low level to the logic high level. The 3-a-th transistor T23a, the 3-b-th to 3-d-th transistors, the 5-a-th transistor T25a, and the 5-b-th to 5-d-th transistors may be turned on based on the i−2-th scan signal GCi and the i+1-2-th scan signal GCi+1. The first reference voltage Vref may be provided to the 3-a-th node n23a and the 3-b-th to 3-d-th nodes through the turn-on operations of the 3-a-th transistor T23a and the 3-b-th to 3-d-th transistors. In addition, the control terminal and first terminal of the 1-a-th transistor T21a and the 1-b-th to the 1-d-th transistors may be connected to each other through the turn-on operations of the 5-a-th transistor T25a and the 5-b-th to 5-d-th transistors.

At a time point t84, the i−2-th scan signal GCi and the i+1-2-th scan signal GCi+1 may transition from the logic high level to the logic low level. The 3-a-th transistor T23a, the 3-b-th to 3-d-th transistors, the 5-a-th transistor T25a, and the 5-b-th to 5-d-th transistors may be turned off based on the i−2-th scan signal GCi.

During the compensation period Tc between the time point t83 and the time point t84, the ninth transistor T29, the 3-a-th transistor T23a, the 3-b-th to 3-d-th transistors, the 5-a-th transistor T25a, and the 5-b-th to 5-d-th transistors may be turned on. The 1-a-th transistor T11a and the 1-b-th to the 1-d-th transistors may respectively be operated as the diodes through the 3-a-th transistor T23a, and the 3-b-th to 3-d-th transistors during the compensation period Tc. During the compensation period Tc, the voltage at the 3-a-th node n23a and the 3-b-th to 3-d-th nodes may be maintained at the first reference voltage Vref.

At a time point t85, the k-th group light-emitting signal EMk may transition from the logic low level to the logic high level. The ninth transistor T29 may be turned off.

At a time point t86, the i−1-th scan signal GWi may transition from the logic low level to the logic high level. The 2-a-th transistor T22a and the 2-b-th transistor may be turned on based on the i−1-th scan signal GWi. The 3-a-th node n23a and the j-th data line DLj may be connected to each other based on the turn-on operation of the 2-a-th transistor T22a, and the 1-b-th node and the j+1-th data line DLj+1 may be connected to each other based on the turn-on operation of the 2-b-th transistor.

At a time point t87, the i−1-th scan signal GWi may transition from the logic high level to the logic low level. The 2-a-th transistor T22a and the 2-b-th transistor may be turned off based on the i−1-th scan signal GWi.

The data voltage corresponding to a current to be provided to the a-th light-emitting element OLEDa may be provided to the 3-a-th node n23a through the j-th data line DLj, and the data voltage corresponding to a current to be provided to the b-th light-emitting element may be provided to the 3-b-th node through the j+1-th data line DLj+1, through the turn-on operations of the 2-a-th transistor T22a and the 2-b-th transistor during the first data writing period Tw1 between the time point t86 and the time point t87.

During the first data writing period Tw1, the voltage at the 3-a-th node n23a may be changed from the first reference voltage Vref to the data voltage of the j-th data line DLj, and the 1-a-th capacitor Cst2a may store the voltage that reflects the threshold voltage of the 1-a-th transistor T21a based on the data voltage of the j-th data line DLj. Similarly, during the first data writing period Tw1, the voltage at the 3-b-th node may be changed from the first reference voltage Vref to the data voltage of the j+1-th data line DLj+1, and the 1-b-th capacitor may store the voltage that reflects the threshold voltage of the 1-b-th transistor based on the data voltage of the j+1-th data line DLj+1.

At a time point t88, the i+1-1-th scan signal GWi+1 may transition from the logic low level to the logic high level. The 2-c-th transistor and the 2-d-th transistor may be turned on based on the i+1-1-th scan signal GWi+1. The 3-c-th node and the j-th data line DLj may be connected to each other based on the turn-on operation of the 2-c-th transistor, and the 3-d-th node and the j+1-th data line DLj+1 may be connected to each other based on the turn-on operation of the 2-d-th transistor.

At a time point t89, the i+1-1-th scan signal GWi+1 may transition from the logic high level to the logic low level. The 2-c-th transistor and the 2-d-th transistor may be turned off based on the i+1-1-th scan signal GWi+1.

The data voltage corresponding to a current to be provided to the c-th light-emitting element may be provided to the 3-c-th node through the j-th data line DLj, and the data voltage corresponding to a current to be provided to the d-th light-emitting element may be provided to the 3-d-th node through the j+1-th data line DLj+1, through the turn-on operations of the 2-c-th transistor and the 2-d-th transistor during the second data writing period Tw2 between the time point t88 and the time point t89.

During the second data writing period Tw2, the voltage at the 3-c-th node may be changed from the first reference voltage Vref to the data voltage of the j-th data line DLj, and the 1-c-th capacitor may store the voltage that reflects the threshold voltage of the 1-c-th transistor based on the data voltage of the j-th data line DLj. Similarly, during the second data writing period Tw2, the voltage at the 1-d-th node may be changed from the first reference voltage Vref to the data voltage of the j+1-th data line DLj+1, and the 1-d-th capacitor may store the voltage that reflects the data voltage of the j+1-th data line DLj+1 and the threshold voltage of the 1-d-th transistor based on the first reference voltage Vref.

At a time point t90, the k-th group initialization signal GBk may transition from the logic high level to the logic low level. The 7-a-th transistor T27a, the 7-b-th to 7-d-th transistors, and the eighth transistor T28 may be turned on based on the k-th group initialization signal GBk. The light-emission initialization voltage Vaint may be provided to the 4-a-th node n24a and the 4-b-th to 4-d-th nodes through the turn-on operations of the 7-a-th transistor T27a and the 7-b-th to 7-d-th transistors. The second reference voltage Vbias may be provided to the fifth node n25, which is the common node cn2, through the turn-on operation of the eighth transistor T28.

At a time point t91, the k-th group initialization signal GBk may transition from the logic low level to the logic high level. The 7-a-th transistor T27a, the 7-b-th to 7-d-th transistors, and the eighth transistor T28 may be turned off based on the k-th group initialization signal GBk.

During the light-emission initialization period Tai between the time point t90 and the time point t91, the initialization operation may be performed before the light-emitting operation on the anodes AE of the a-th light-emitting element OLEDa and the b-th to d-th light-emitting elements. In addition, the second reference voltage Vbias may be provided to the fifth node n25, which is the common node cn2. Accordingly, the fifth node n25 may be initialized to emit light based on the second reference voltage Vbias.

At a time point t92, the k-th group light-emitting signal EMk, the i-th light-emitting signal EMBi, and the i+1-th light-emitting signal EMBi+1 may transition from the logic high level to the logic low level. The ninth transistor T29 may be turned on based on the k-th group light-emitting signal EMk. The 6-a-th transistor T26a and the 6-b-th to 6-d-th transistors may be turned on based on the i-th light-emitting signal EMBi and the i+1-th light-emitting signal EMBi+1.

FIG. 17 shows that the k-th group light-emitting signal EMk and the i-th light-emitting signal EMBi transition simultaneously to the logic low level. However, the present disclosure is not limited thereto, and the k-th group light-emitting signal EMk and the i-th light-emitting signal EMBi may transition to the logic low level at different time points according to an embodiment.

The a-th pixel Pa4 and the b-th to d-th pixels may respectively provide paths of the light-emitting current for the a-th light-emitting element OLEDa and the b-th to d-th light-emitting elements through the turn-on operations of the ninth transistor T29, the 6-a-th transistor T26a, and the 6-b-th to 6-d-th transistors during the light emission period Te after the time point t92. In addition, the 1-a-th transistor T21a and the 1-b-th to 1-d-th transistors may respectively be turned on based on the voltage at the 1-a-th node n21a and the 1-b-th to 1-d-th nodes, stored in the 1-a-th capacitor Cst1a and the 1-b-th to 1-d-th capacitors to thus respectively provide the light-emitting current to the light-emitting elements. The a-th light-emitting element OLEDa and the b-th to d-th light-emitting elements may respectively emit light based on the light-emitting current.

Although the embodiments of the present disclosure have been described in detail hereinabove, the scope of the present disclosure is not limited thereto, and may include various modifications and alterations made by those skilled in the art using a basic spirit of the present disclosure as defined in the claims.

A display device according to an embodiment may be applied to various electronic devices. An electronic device according to an embodiment may include the display device, and may further include modules or devices having additional functions other than the display device.

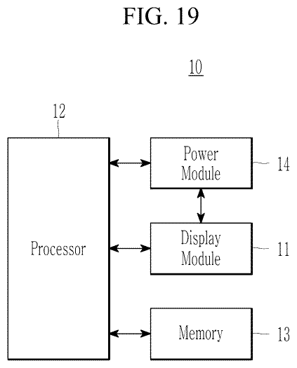

FIG. 19 is a block diagram of an electronic device according to some embodiments. Referring to FIG. 19, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

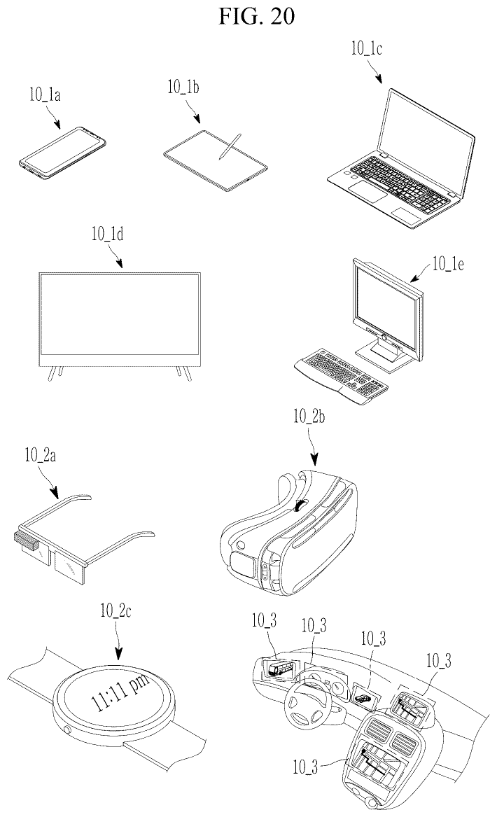

FIG. 20 shows schematic diagrams of electronic devices according to various embodiments.

Referring to FIG. 20, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

What is claimed is:

1. A display device comprising:
a first light-emitting element and a second light-emitting element;
a first transistor configured to connect a first data line and a first node to each other based on a first signal;
a first capacitor including a first electrode connected to the first node, and configured to store a first voltage based on a data signal transmitted through the first data line and corresponding to a first current to be provided to the first light-emitting element;
a second transistor connected between the first light-emitting element and a common node, and configured to provide the first current based on the first voltage to the first light-emitting element;
a third transistor configured to connect the first data line and a second node to each other based on a second signal different from the first signal;
a second capacitor including a first electrode connected to the second node, and configured to store a second voltage based on a data signal transmitted through the first data line and corresponding to a second current to be provided to the second light-emitting element;
a fourth transistor connected between the second light-emitting element and the common node, and configured to provide the second current based on the second voltage to the second light-emitting element; and
a fifth transistor configured to connect a power voltage line and the common node to each other based on a third signal.

2. The device of claim 1, further comprising
a sixth transistor configured to provide a first reference voltage to the common node based on a fourth signal.

3. The device of claim 2, further comprising:
a seventh transistor configured to provide a second reference voltage to the first node based on a fifth signal;
an eighth transistor configured to provide an initialization voltage to an anode of the first light-emitting element based on a sixth signal;
a ninth transistor configured to provide the second reference voltage to the second node based on a seventh signal; and
a tenth transistor configured to provide the initialization voltage to an anode of the second light-emitting element based on an eighth signal,
wherein the second transistor is configured to provide the first current to the first light-emitting element through a third node,
the fourth transistor is configured to provide the second current to the second light-emitting element through a fourth node,
a second electrode of the first capacitor is connected to the third node, and
a second electrode of the second capacitor is connected to the fourth node.

4. The device of claim 3, wherein
the sixth transistor, the eighth transistor, and the tenth transistor are configured to be turned on simultaneously.

5. The device of claim 2, further comprising:
a third capacitor including a first electrode connected to the first node and a second electrode connected to the power voltage line;
a fourth capacitor including a first electrode connected to the second node and a second electrode connected to the power voltage line;
a seventh transistor configured to provide a second reference voltage to the first node based on a fifth signal;
an eighth transistor configured to connect a third node and a control terminal of the second transistor to each other based on the fifth signal;
a ninth transistor configured to provide the second reference voltage to the second node based on a sixth signal; and
a tenth transistor configured to connect a fourth node and a control terminal of the fourth transistor to each other based on the sixth signal,
wherein the first capacitor is connected between the first node and the control terminal of the second transistor, and
the second capacitor is connected between the second node and the control terminal of the fourth transistor.

6. The device of claim 5, further comprising
an eleventh transistor configured to provide a light-emission initialization voltage to an anode of the first light-emitting element based on the fourth signal.

7. The device of claim 5, wherein
the first transistor, the seventh transistor, and the eighth transistor are P-type metal oxide semiconductor (PMOS) transistors.

8. The device of claim 5, wherein
the first transistor, the seventh transistor, and the eighth transistor are N-type metal oxide semiconductor (NMOS) transistors, and
the second transistor, the fifth transistor, and the sixth transistor are P-type metal oxide semiconductor (PMOS) transistors.

9. The device of claim 2, further comprising:
a third light-emitting element and a fourth light-emitting element;
a seventh transistor configured to connect a second data line, which is different from the first data line, and a third node to each other based on the first signal;
a third capacitor including one electrode connected to the third node, and configured to store a third voltage based on a data signal transmitted through the second data line and corresponding to a third current to be provided to the third light-emitting element;
an eighth transistor connected between the common node and the third light-emitting element, and configured to provide the third current based on the third voltage to the third light-emitting element;
a ninth transistor configured to connect the second data line and a fourth node to each other based on the second signal;
a fourth capacitor including one electrode connected to the fourth node, and configured to store a fourth voltage based on a data signal transmitted through the second data line and corresponding to a fourth current to be provided to the fourth light-emitting element; and
a tenth transistor connected between the common node and the fourth light-emitting element, and configured to provide the fourth current based on the fourth voltage to the fourth light-emitting element.

10. The device of claim 2, wherein
the first transistor, the third transistor, and the fifth transistor are configured to be turned on sequentially, and the first and second light-emitting elements are configured to emit light.

11. A display device comprising:
a first light-emitting element and a second light-emitting element;
a first transistor configured to connect a first data line and a first node to each other based on a first signal;
a first capacitor connected between the first node and a second node, and configured to store a first voltage based on a data signal transmitted through the first data line and corresponding to a first current to be provided to the first light-emitting element;
a second transistor connected between the second node and a common node, and configured to provide the first current based on the first voltage to the first light-emitting element;
a third transistor configured to connect the first data line and a third node to each other based on a second signal different from the first signal;
a second capacitor connected between the third node and a fourth node, and configured to store a second voltage based on a data signal transmitted through the first data line corresponding to a second current to be provided to the second light-emitting element;
a fourth transistor connected between the fourth node and the common node, and configured to provide the second current based on the second voltage to the second light-emitting element; and
a fifth transistor configured to connect a power voltage line and the common node to each other based on a third signal.

12. The device of claim 11, further comprising:
a third light-emitting element and a fourth light-emitting element;
a sixth transistor configured to connect a second data line, which is different from the first data line, and a fifth node to each other based on the first signal;
a third capacitor connected between the fifth node and a sixth node, and configured to store a third voltage based on a data signal transmitted through the second data line and corresponding to a third current to be provided to the third light-emitting element;
a seventh transistor connected between the common node and the third light-emitting element, and configured to provide the third current based on the third voltage to the third light-emitting element;
an eighth transistor configured to connect the second data line and a seventh node to each other based on the second signal;
a fourth capacitor connected between the seventh node and an eighth node, and configured to store a fourth voltage based on a data signal transmitted through the second data line and corresponding to a fourth current to be provided to the fourth light-emitting element; and
a ninth transistor connected between the common node and the fourth light-emitting element, and configured to provide the fourth current based on the fourth voltage to the fourth light-emitting element.

13. The device of claim 12, wherein
the first transistor and the second transistor are disposed in a first area,
the third transistor and the fourth transistor are disposed in a second area adjacent to the first area in a first direction in which the first data line extends,
the sixth transistor and the seventh transistor are disposed in a third area adjacent to the first area in a second direction intersecting the first direction,
the eighth transistor and the ninth transistor are disposed in a fourth area adjacent to the second area in the second direction and adjacent to the third area in the first direction, and
the fifth transistor is disposed in a fifth area disposed between the first to fourth areas.

14. The device of claim 13, further comprising:
a fifth capacitor connected between the second node and a power voltage line;
a sixth capacitor connected between the fourth node and the power voltage line
a seventh capacitor connected between the sixth node and the power voltage line; and
an eighth capacitor connected between the eighth node and the power voltage line,
wherein one electrode of each of the fifth to eighth capacitors is disposed in the fifth area.

15. The device of claim 13, further comprising
a tenth transistor configured to provide a first reference voltage to the common node based on a fourth signal,
wherein the tenth transistor is disposed in the fifth area.

16. The device of claim 11, wherein
while compensation operations are performed on the second transistor and the fourth transistor,
the second transistor and the fourth transistor are configured to operate as source followers.

17. The device of claim 16, wherein
the first to fifth transistors are N-type metal oxide semiconductor (NMOS) transistors.

18. An electronic device comprising:
a plurality of pixels including a first pixel and a second pixel, wherein the first pixel and the second pixel share a common circuit disposed therebetween and are connected to a first data line;
a scan driver configured to provide a scan signal to each of the plurality of pixels; and
a light emission driver configured to provide a light-emitting signal to each of the plurality of pixels,
wherein each of the first pixel and the second pixel includes
a first light-emitting element,
a first transistor configured to connect the first data line and a first node to each other based on a first signal,
a first capacitor including one electrode connected to the first node, and configured to store a first voltage based on a data signal transmitted through the first data line and corresponding to a first current to be provided to the first light-emitting element, and
a second transistor connected between a common node and the first light-emitting element, and configured to provide the first current based on the first voltage to the first light-emitting element, and
wherein the common circuit includes a third transistor configured to connect the common node and a power voltage line to each other based on the light-emitting signal.

19. The device of claim 18, wherein
the plurality of pixels further include a third pixel and a fourth pixel connected to a second data line, which is different from the first data line, and sharing the common circuit, and
each of the third pixel and the fourth pixel includes
a second light-emitting element,
a first transistor configured to connect the second data line and a second node to each other based on a second signal,
a second capacitor including one electrode connected to the second node, and configured to store a second voltage based on a data signal transmitted through the second data line and corresponding to a second current to be provided to the second light-emitting element, and
a second transistor connected between the common node and the second light-emitting element, and configured to provide the second current based on the second voltage to the second light-emitting element.

20. The device of claim 19, wherein
the first pixel and the second pixel are adjacent to each other in a first direction in which the first data line extends,
the first pixel and the third pixel are adjacent to each other in a second direction intersecting the first direction,
the fourth pixel is adjacent to the third pixel in the first direction and adjacent to the second pixel in the second direction, and
the common circuit is disposed between the first to fourth pixels.

21. An electronic device comprising:
a memory;
a processor executing an application stored in the memory; and
a display device comprising a display module outputting video information provided by the application,
wherein the display device comprises:
a first light-emitting element and a second light-emitting element;
a first transistor configured to connect a first data line and a first node to each other based on a first signal;
a first capacitor including a first electrode connected to the first node, and configured to store a first voltage based on a data signal transmitted through the first data line and corresponding to a first current to be provided to the first light-emitting element;
a second transistor connected between the first light-emitting element and a common node, and configured to provide the first current based on the first voltage to the first light-emitting element;
a third transistor configured to connect the first data line and a second node to each other based on a second signal different from the first signal;
a second capacitor including a first electrode connected to the second node, and configured to store a second voltage based on a data signal transmitted through the first data line and corresponding to a second current to be provided to the second light-emitting element;
a fourth transistor connected between the second light-emitting element and the common node, and configured to provide the second current based on the second voltage to the second light-emitting element; and
a fifth transistor configured to connect a power voltage line and the common node to each other based on a third signal.
